(19) United States
(12) Patent Application Publication
(10) Pub. No.: US 2024/0324307 A1
(43) Pub. Date: Sep. 26, 2024

(54) LIGHT-EMITTING APPARATUS

(71) Applicant: Semiconductor Energy Laboratory Co., Ltd., Atsugi-shi, Kanagawa-ken (JP)

(72) Inventors: Nobuharu OHSAWA, Zama (JP); Toshiki SASAKI, Kawasaki (JP); Tsunenori SUZUKI, Yokohama (JP); Naoaki HASHIMOTO, Sagamihara (JP)

(21) Appl. No.: 18/578,120

(22) PCT Filed: Jul. 8, 2022
(86) PCT No.: PCT/IB2022/056311

§ 371 Date: Jan. 10, 2024

(30) Foreign Application Priority Data
Jul. 21, 2021 (JP) 2021-120866
Aug. 20, 2021 (JP) 2021-134538

(51) Int. Cl. H10K 59/122

(52) U.S. Cl. CPC H10K 59/122

(57) ABSTRACT

A high-resolution light-emitting apparatus that emits blue light with a high blue index is provided. The light-emitting apparatus includes a pixel electrode A; a pixel electrode B adjacent to the pixel electrode A; a common electrode; an EL layer A sandwiched between the pixel electrode A and the common electrode; an EL layer B sandwiched between the pixel electrode B and the common electrode; and an insulating layer positioned between the common electrode and each of the EL layer A and the EL layer B. The insulating layer has an opening portion A overlapping with the pixel electrode A and an opening portion B overlapping with the pixel electrode B. The EL layer A includes a light-emitting layer A. The light-emitting layer A contains a light-emitting substance A. The light-emitting substance A emits blue light. The EL layer A is in contact with the pixel electrode A. The EL layer B is in contact with the pixel electrode B. The EL layer A is in contact with the common electrode in the opening portion A. The EL layer B is in contact with the common electrode in the opening portion B.

### TECHNICAL FIELD

One embodiment of the present invention relates to an organic compound, a light-emitting device, a display module, a lighting module, a display apparatus, a light-emitting apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. Alternatively, one embodiment of the present invention relates to a process, a machine, manufacture, or a composition of matter. Accordingly, more specific examples of the technical field of one embodiment of the present invention disclosed in this specification include a semiconductor device, a display apparatus, a liquid crystal display apparatus, a light-emitting apparatus, a lighting device, a power storage device, a memory device, an imaging device, a driving method thereof, and a manufacturing method thereof.

### BACKGROUND ART

Light-emitting devices (organic EL devices) including organic compounds and utilizing electroluminescence (EL) have been put to more practical use. In the basic structure of such light-emitting devices, an organic compound layer containing a light-emitting material (an EL layer) is held between a pair of electrodes. Carriers are injected by application of voltage to the device, and recombination energy of the carriers is used, whereby light emission can be obtained from the light-emitting material.

Such light-emitting devices are of self-luminous type and thus have advantages over liquid crystal devices, such as high visibility and no need for a backlight when used for pixels of a display, and are particularly suitable for flat panel displays. Displays including such light-emitting devices are also highly advantageous in that they can be thin and lightweight. Another feature is an extremely fast response speed.

Since light-emitting layers of such light-emitting devices can be successively formed two-dimensionally, planar light emission can be obtained. This feature is difficult to realize with point light sources typified by incandescent lamps and LEDs or linear light sources typified by fluorescent lamps; thus, the light-emitting devices also have great potential as planar light sources, which can be used for lighting and the like.

Light-emitting apparatuses including light-emitting devices are suitable for a variety of electronic appliances as described above, and research and development of light-emitting devices have progressed for better characteristics.

In order to obtain a higher-resolution light-emitting apparatus using an organic EL device, patterning an organic layer by a photolithography method using a photoresist or the like, instead of an evaporation method using a metal mask, has been studied. By using the photolithography method, a high-resolution light-emitting apparatus in which the distance between EL layers is several micrometers can be obtained (see Patent Document 1, for example).

### REFERENCE

### Patent Document

[Patent Document 1] Japanese Translation of PCT International Application No. 2018-521459

### SUMMARY OF THE INVENTION

### Problems to be Solved by the Invention

In a high-resolution light-emitting apparatus in which the distance between EL layers is several micrometers, a structure of a peripheral portion of a pixel electrode tends to have a great influence because of a small pixel area. For example, when light is emitted through a microcavity structure with a different optical path length unintentionally in a peripheral portion of a pixel electrode owing to leakage current, an emission spectrum becomes broad and thus color purity is degraded. This is noticeable in a blue-light-emitting device with a short optical path length in a microcavity structure, leading to a significant decrease in blue index.

In view of the above, an object of one embodiment of the present invention is to provide a high-resolution light-emitting apparatus that emits blue light with a high blue index.

### Means for Solving the Problems

Thus, one embodiment of the present invention is a light-emitting apparatus including a pixel electrode A; a pixel electrode B adjacent to the pixel electrode A; a common electrode; an EL layer A sandwiched between the pixel electrode A and the common electrode; an EL layer B sandwiched between the pixel electrode B and the common electrode; and an insulating layer positioned between the common electrode and each of the EL layer A and the EL layer B. The insulating layer has an opening portion A overlapping with the pixel electrode A and an opening portion B overlapping with the pixel electrode B. The EL layer A includes a light-emitting layer A. The light-emitting layer A contains a light-emitting substance A. The light-emitting substance A emits blue light. The EL layer A is in contact with the pixel electrode A. The EL layer B is in contact with the pixel electrode B. The EL layer A is in contact with the common electrode in the opening portion A. The EL layer B is in contact with the common electrode in the opening portion B.

Another embodiment of the present invention is the light-emitting apparatus having the above structure, in which an end portion of the pixel electrode A is covered with the EL layer A and an end portion of the pixel electrode B is covered with the EL layer B.

Another embodiment of the present invention is the light-emitting apparatus having the above structure, in which an end portion of the EL layer A is covered with the insulating layer and an end portion of the EL layer B is covered with the insulating layer.

Another embodiment of the present invention is a light-emitting apparatus including a pixel electrode A; a pixel electrode B adjacent to the pixel electrode A; a common electrode; an EL layer A sandwiched between the pixel electrode A and the common electrode; an EL layer B sandwiched between the pixel electrode B and the common electrode; and an insulating layer positioned between the common electrode and each of the EL layer A and the EL layer B. The insulating layer has an opening portion A overlapping with the pixel electrode A and an opening portion B overlapping with the pixel electrode B. The EL layer A includes a first EL layer A including a light-emitting layer A and a second EL layer positioned between the first EL layer A and the common electrode. The EL layer B includes a first EL layer B including a light-emitting layer B and the second EL layer positioned between the first EL layer B and the common electrode. The light-emitting layer A contains a light-emitting substance A. The light-emitting substance A emits blue light. The first EL layer A is in contact with the pixel electrode A. The first EL layer B is in contact with the pixel electrode B. The second EL layer A is in contact with the first EL layer A in the opening portion A. The second EL layer B is in contact with the first EL layer B in the opening portion B.

Another embodiment of the present invention is the light-emitting apparatus having the above structure, in which the second EL layer is positioned between and in contact with the insulating layer and the common electrode in a region overlapping with neither the pixel electrode A nor the pixel electrode B.

Another embodiment of the present invention is the light-emitting apparatus having the above structure, in which an end portion of the pixel electrode A is covered with the first EL layer A and an end portion of the pixel electrode B is covered with the first EL layer B.

Another embodiment of the present invention is the light-emitting apparatus having the above structure, in which an end portion of the first EL layer A is covered with the insulating layer and an end portion of the first EL layer B is covered with the insulating layer.

Another embodiment of the present invention is the light-emitting apparatus having the above structure, in which the insulating layer contains an organic compound.

Another embodiment of the present invention is the light-emitting apparatus having the above structure, in which side surfaces of the opening portion A and the opening portion B are tapered and the taper angle is less than 90°.

Another embodiment of the present invention is the light-emitting apparatus having the above structure, in which a distance between opposite end portions of the pixel electrode A and the pixel electrode B is longer than or equal to 0.5 m and shorter than or equal to 5 μm.

Another embodiment of the present invention is the light-emitting apparatus having the above structure, in which an area of a portion where the EL layer A is in contact with the pixel electrode A and the common electrode, and the pixel electrode A, the EL layer A, and the common electrode overlap with one another is greater than or equal to 5 μm² and less than or equal to 15 μm².

Another embodiment of the present invention is the light-emitting apparatus having the above structure, in which a half width of an emission spectrum of the EL layer A in the opening portion A is less than or equal to 20 nm.

Another embodiment of the present invention is the light-emitting apparatus having the above structure, in which a half width of an emission spectrum of the light-emitting substance A is less than or equal to 30 nm.

Another embodiment of the present invention is an electronic appliance including the light-emitting apparatus having any of the above structures and a sensor, an operation button, a speaker, or a microphone.

Note that the light-emitting apparatus in this specification includes, in its category, an image display device that uses a light-emitting device. The light-emitting apparatus may also include a module in which a light-emitting device is provided with a connector such as an anisotropic conductive film or a TCP (Tape Carrier Package), a module in which a printed wiring board is provided at the end of a TCP, and a module in which an IC (integrated circuit) is directly mounted on a light-emitting device by a COG (Chip On Glass) method. Furthermore, a lighting device or the like may include the light-emitting apparatus.

### Effect of the Invention

One embodiment of the present invention can provide a high-resolution light-emitting apparatus that emits blue light with a high blue index.

Note that the description of these effects does not preclude the existence of other effects. Note that one embodiment of the present invention does not need to have all these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A, FIG. 1B, and FIG. 1C are schematic views of light-emitting devices.

FIG. 2A and FIG. 2B are schematic views of light-emitting devices.

FIG. 3A and FIG. 3B are diagrams illustrating an active matrix light-emitting apparatus.

FIG. 4A and FIG. 4B are diagrams illustrating active matrix light-emitting apparatuses.

FIG. 5 is a diagram illustrating an active matrix light-emitting apparatus.

FIG. 6A and FIG. 6B are diagrams illustrating a passive matrix light-emitting apparatus.

FIG. 7A to FIG. 7D are diagrams illustrating a structure example of a display apparatus.

FIG. 8A to FIG. 8F are diagrams illustrating an example of a method for fabricating a display apparatus.

FIG. 9A to FIG. 9F are diagrams illustrating an example of a method for fabricating a display apparatus.

FIG. 10A and FIG. 10B are diagrams illustrating a lighting device.

FIG. 11A, FIG. 11B1, FIG. 11B2, and FIG. 11C are diagrams illustrating electronic appliances.

FIG. 12A, FIG. 12B, and FIG. 12C are diagrams illustrating electronic appliances.

FIG. 13 is a diagram illustrating a lighting device.

FIG. 14 is a diagram illustrating a lighting device.

FIG. 15 is a diagram illustrating in-vehicle display apparatuses and lighting devices.

FIG. 16A and FIG. 16B are diagrams illustrating an electronic appliance.

FIG. 17A, FIG. 17B, and FIG. 17C are diagrams illustrating an electronic appliance.

FIG. 18 is a diagram illustrating a structure example of a display apparatus.

FIG. 19 is a graph showing the current efficiency-luminance characteristics of a light-emitting device 1, a light-emitting device 2, and a comparative light-emitting device 1.

FIG. 20 is a graph showing the blue index-current density characteristics of the light-emitting device 1, the light-emitting device 2, and the comparative light-emitting device 1.

FIG. 21 is a graph showing the emission spectra of the light-emitting device 1, the light-emitting device 2, and the comparative light-emitting device 1.

FIG. 22 shows 2D spectroradiometer measurement results in Example.

FIG. 23 shows 2D spectroradiometer measurement results in Example.

FIG. 24A and FIG. 24B are graphs showing EL intensity measured with a 2D spectroradiometer.

FIG. 25A and FIG. 25B are graphs showing EL intensity measured with a 2D spectroradiometer.

FIG. 26A is a diagram illustrating a light-emitting device in Example, and FIG. 26B is a diagram showing a cross-sectional STEM image explaining a light emission mechanism and an image obtained with a 2D spectroradiometer in Example.

### MODE FOR CARRYING OUT THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

In this specification and the like, a device formed using a metal mask or an FMM (fine metal mask, high-resolution metal mask) may be referred to as a device having an MM (metal mask) structure. In addition, in this specification and the like, a device formed without using a metal mask or an FMM may be referred to as a device having an MML (metal maskless) structure.

### Embodiment 1

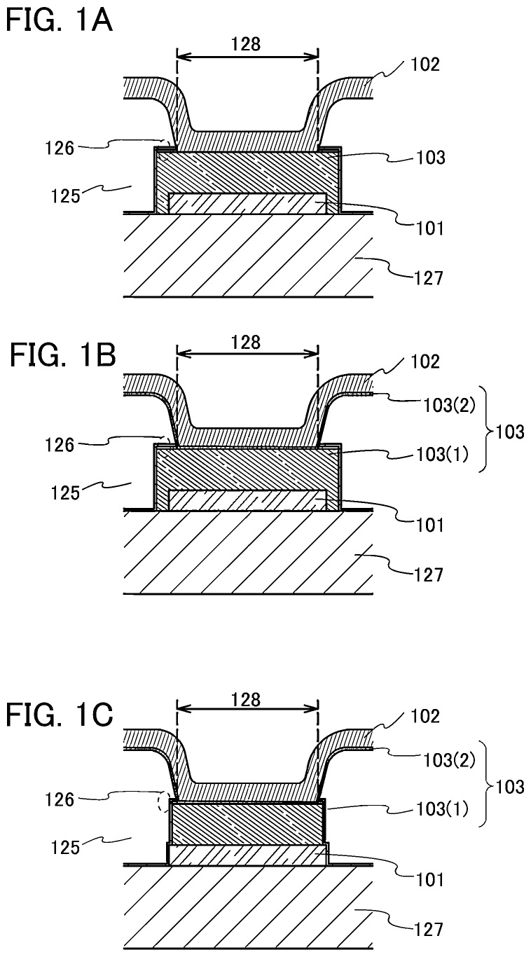

FIG. 1A is a diagram illustrating a light-emitting device in a light-emitting apparatus of one embodiment of the present invention. The light-emitting device includes an EL layer 103 between a pair of electrodes (a pixel electrode (anode) 101 and a common electrode (cathode) 102). The EL layer 103 is in contact with the pixel electrode 101 and the common electrode 102, and light is emitted when current is made to flow by voltage application between the pixel electrode 101 and the common electrode 102. The light-emitting apparatus of one embodiment of the present invention includes a plurality of such light-emitting devices.

As illustrated in FIG. 1B, the EL layer 103 may include a first EL layer 103(1) that includes a light-emitting layer and a second EL layer 103(2) that is positioned between the first EL layer 103(1) and the common electrode 102 and is in contact with the first EL layer 103(1) and the common electrode 102. Note that the second EL layer 103(2) can be any of layers closer to the cathode side than the light-emitting layer is (a hole-blocking layer, an electron-transport layer, and an electron-injection layer), and is preferably an electron-injection layer.

The EL layer 103 (the EL layer 103(1) in the case where the EL layer 103(2) is provided) is divided between the light-emitting devices adjacent to each other in at least one direction. The EL layer 103 (the EL layer 103(1)) may be provided to cover at least a pair of sides of the pixel electrode 101 as illustrated in FIG. 1A and FIG. 1B; alternatively, as illustrated in FIG. 1C, the end portions of the EL layer 103 (the EL layer 103(1)) may be positioned inward from the end portions of the pixel electrode 101.

At least a pair of opposite end portions of the EL layer 103 (the EL layer 103(1) in the case where the EL layer 103(2) is provided) are covered with an insulating layer 125 containing an organic compound. An opening portion 128 overlapping with the pixel electrode 101 is formed in the insulating layer 125.

The common electrode 102 is in contact with the EL layer 103 (the EL layer 103(2) in the case where the EL layer 103(2) is provided) in the opening portion 128.

Note that an insulating layer 126 may be provided between the EL layer 103 (the EL layer 103(1)) and the insulating layer 125. The insulating layer 126 preferably contains an inorganic compound and further preferably contains aluminum oxide. It is preferable that an upper portion of the EL layer 103 (the EL layer 103(1)) have a two-layer structure and a side surface thereof have a single-layer structure so that the top surface is thicker than the side surface.

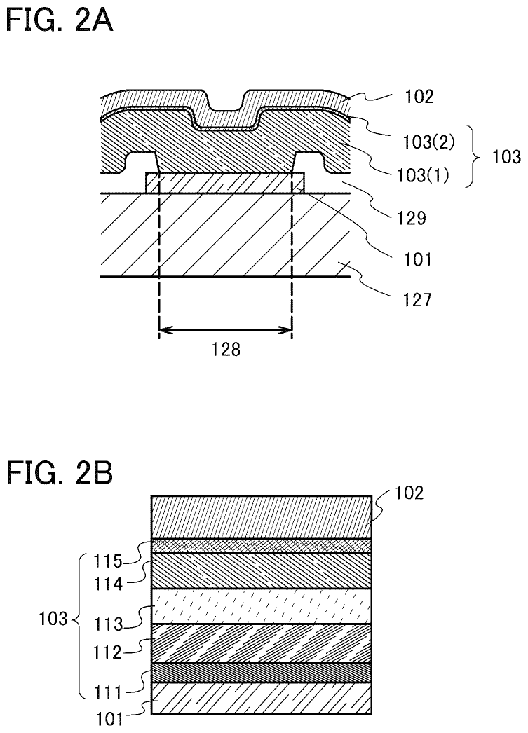

The EL layer 103 preferably has a stacked-layer structure illustrated in FIG. 2B, and includes at least a light-emitting layer 113. Besides, a hole-injection layer 111, a hole-transport layer 112, the light-emitting layer 113, an electron-transport layer 114, an electron-injection layer 115, and the like may be included. In addition, a hole-blocking layer, an electron-blocking layer, an exciton-blocking layer, an intermediate layer (a charge-generation layer), and the like may be included. Note that since these are examples, the layers other than the light-emitting layer 113 are not necessarily provided, and a layer having a plurality of functions may be formed instead.

The light-emitting layer 113 contains a light-emitting substance. In this embodiment, the light-emitting substance is preferably a substance that emits blue light (with an emission peak wavelength greater than or equal to 440 nm and less than or equal to 480 nm, preferably greater than or equal to 455 nm and less than or equal to 465 nm), in which case a more significant effect can be obtained. In the case where a blue-light-emitting substance is used as the light-emitting substance, the half width of its emission spectrum is preferably less than or equal to 30 nm.

FIG. 2A illustrates a light-emitting device having a structure different from the structure in FIG. 1. In the light-emitting device illustrated in FIG. 2A, the insulating layer 125 in the light-emitting device illustrated in FIG. 1 is not provided, an insulating layer 129 that covers the end portions of the pixel electrode 101 is formed, and the EL layer 103 is in contact with the pixel electrode in the opening portion 128 provided in the insulating layer 129. The EL layer 103 is continuously provided, and the common electrode 102 is in contact with the top surface of the EL layer 103 in a wider range than the pixel electrode.

In particular, in the case where the conductivity of the hole-injection layer positioned on the pixel electrode (anode) 101 side is high in the light-emitting device having the structure illustrated in FIG. 2A, current flows not only to the common electrode that is in a position overlapping with the opening portion of the insulating film but also to the common electrode positioned in its peripheral portion unintentionally in some cases. The emission position of light excited by the current (leakage current) is different from the assumed position; thus, the optical path length of part of light from the inside of the light-emitting device to the outside of the device may shift from the assumed wavelength range.

The angle of the common electrode varies depending on the position because of the unevenness of the insulating layer 129; thus, such light is easily emitted to the outside of the light-emitting device.

For this reason, light with a wavelength longer than the assumed wavelength is mixed in light emitted from the light-emitting device having the structure illustrated in FIG. 2A, so that the emission spectrum becomes broad and the emission peak is shifted to the longer wavelength side. The color purity is accordingly degraded; in particular, a decrease in blue index is significant.

Note that the blue index (BI) is a value obtained by dividing current efficiency (cd/A) by chromaticity y, and is one of the indicators of characteristics of blue light emission. As the chromaticity y is smaller, the color purity of blue light emission tends to be higher. With high color purity for blue light emission, a wide range of blue can be expressed even with a small number of luminance components; thus, using blue light emission with high color purity reduces the luminance needed for expressing blue, leading to lower power consumption. Thus, BI that is based on chromaticity y, which is one of the indicators of color purity of blue, is suitably used as a means for showing efficiency of blue light emission. The light-emitting device with higher BI can be regarded as a blue-light-emitting device having higher efficiency for a display.

Meanwhile, in the light-emitting device of one embodiment of the present invention illustrated in each of FIG. 1A to FIG. 1C, the common electrode 102 overlaps with the EL layer 103 (the EL layer 103(1)) in the opening portion 128 of the insulating layer 126. Since leakage current hardly flows to the peripheral portion of the common electrode 102 and light with a different wavelength is unlikely to be mixed, light emission with high color purity can be obtained and the light-emitting device can have a high blue index. In such a blue-light-emitting device, the half width of the emission spectrum obtained through the opening portion 128 can be less than or equal to 20 nm.

This phenomenon occurs in the peripheral portion of the light-emitting device (the periphery of the portion where the EL layer is in contact with the pixel electrode and the common electrode and they overlap with one another) and thus is more noticeable in a higher-resolution light-emitting apparatus. Hence, the structure of one embodiment of the present invention is extremely suitable for a high-resolution light-emitting apparatus. A high-resolution light-emitting apparatus corresponds to a light-emitting apparatus in which the distance between adjacent pixel electrodes is extremely short, e.g., longer than or equal to 0.5 μm and shorter than or equal to 5 μm, preferably approximately longer than or equal to 0.5 μm and shorter than or equal to 1 μm. Alternatively, a high-resolution light-emitting apparatus corresponds to a light-emitting apparatus in which one light-emitting device has a light-emitting area (an area of a portion where an EL layer is in contact with a pixel electrode and a common electrode and they overlap with one another (without an insulating layer therebetween)) greater than or equal to 5 μm² and less than or equal to 15 μm², preferably greater than or equal to 5 μm² and less than or equal to 10 μm².

With the light-emitting device of one embodiment of the present invention, leakage current (sometimes referred to as horizontal-direction leakage current, horizontal leakage current, or lateral leakage current) that might be generated between the adjacent light-emitting devices can be reduced. For example, in the case where a hole-injection layer is shared by adjacent subpixels, horizontal leakage current might be generated because of the hole-injection layer. Meanwhile, since the EL layer 103 (the EL layer 103(1)) is divided between the light-emitting devices of one embodiment of the present invention adjacent to each other in at least one direction, horizontal leakage current is not generated substantially or horizontal leakage current can be extremely low.

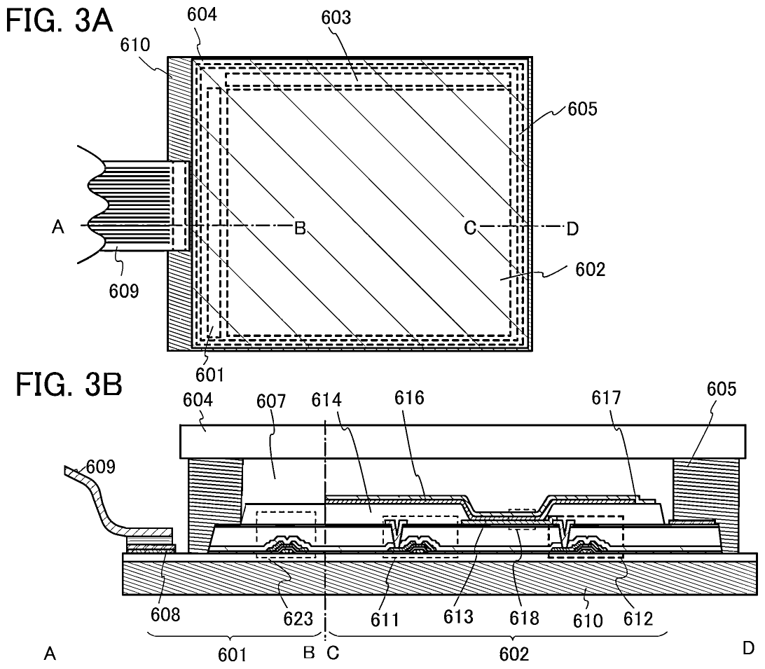

The light-emitting device of one embodiment of the present invention has a wider margin with respect to alignment accuracy between different patterning steps than a light-emitting device illustrated in FIG. 3 and can provide display apparatuses with few variations.

The structure of this embodiment can be used in combination with any of the other structures as appropriate.

### Embodiment 2

Next, examples of other structures and materials of the light-emitting device of one embodiment of the present invention will be described. As described above, the light-emitting device of one embodiment of the present invention includes, between the pair of electrodes of the pixel electrode (anode) 101 and the common electrode (cathode) 102, the EL layer 103 including a plurality of layers. The EL layer 103 includes the light-emitting layer 113 containing at least a light-emitting material and a first organic compound (and a second organic compound), and preferably includes a hole-blocking layer containing a third organic compound.

The anode is preferably formed using any of metals, alloys, and conductive compounds with a high work function (specifically, higher than or equal to 4.0 eV), mixtures thereof, and the like. Specific examples include indium oxide-tin oxide (ITO: Indium Tin Oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, indium oxide-zinc oxide is formed by a sputtering method using a target obtained by adding 1 to 20 wt % of zinc oxide to indium oxide. Furthermore, a film of indium oxide containing tungsten oxide and zinc oxide (IWZO) can be formed by a sputtering method using a target in which tungsten oxide and zinc oxide are added to indium oxide at 0.5 to 5 wt % and 0.1 to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), and nitride of a metal material (e.g., titanium nitride). Graphene can also be used for the anode. Note that when a composite material described later is used for a layer that is in contact with the anode in the EL layer 103, an electrode material can be selected regardless of its work function.

Although the EL layer 103 preferably has a stacked-layer structure, there is no particular limitation on the stacked-layer structure, and any of various layer structures such as a hole-injection layer, a hole-transport layer, a light-emitting layer, an electron-transport layer, an electron-injection layer, a carrier-blocking layer (a hole-blocking layer and an electron-blocking layer), an exciton-blocking layer, and a charge-generation layer can be employed. Note that one or more of the above layers are not necessarily provided. In this embodiment, a structure including the hole-injection layer 111, the hole-transport layer 112, the light-emitting layer 113, the hole-blocking layer, the electron-transport layer 114, and the electron-injection layer 115 as illustrated in FIG. 2B is specifically described below.

The hole-injection layer 111 contains a substance having an acceptor property. Either an organic compound or an inorganic compound can be used as the substance having an acceptor property.

As the substance having an acceptor property, it is possible to use a compound having an electron-withdrawing group (a halogen group or a cyano group); for example, 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylene-1,3,4,5,6,8,9,10-octafluoro-7H-pyren-2-ylidene)malononitrile can be used. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group or a halogen group such as a fluoro group) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, molybdenum oxide, vanadium oxide, ruthenium oxide, tungsten oxide, manganese oxide, or the like can be used, other than the above-described organic compounds. Alternatively, the hole-injection layer 111 can be formed using phthalocyanine (abbreviation: H₂Pc), a phthalocyanine-based complex compound such as copper phthalocyanine (CuPc), an aromatic amine compound such as 4,4′-bis[N-(4-diphenylaminophenyl)-N-phenylamino]biphenyl (abbreviation: DPAB) or N,N-bis{4-[bis(3-methylphenyl)amino]phenyl}-N,N-diphenyl-(1,1′-biphenyl)-4,4′-diamine (abbreviation: DNTPD), or a high molecule such as poly(3,4-ethylenedioxythiophene)/poly(styrenesulfonic acid) (PEDOT/PSS). The substance having an acceptor property can extract electrons from an adjacent hole-transport layer (or hole-transport material) by application of an electric field.

Among substances having an acceptor property, an organic compound having an acceptor property is easy to use because it is easily deposited by vapor deposition.

Alternatively, a composite material in which a hole-transport material contains the above-described substance having an acceptor property can be used for the hole-injection layer 111. By using a composite material in which a hole-transport material contains a substance having an acceptor property, a material used to form an electrode can be selected regardless of its work function. That is, besides a material having a high work function, a material having a low work function can also be used for the anode.

As the hole-transport material used for the composite material, any of a variety of organic compounds such as aromatic amine compounds, carbazole derivatives, aromatic hydrocarbons, and high molecular compounds (e.g., oligomers, dendrimers, and polymers) can be used. Note that the hole-transport material used for the composite material preferably has a hole mobility higher than or equal to 1×10⁻⁶ cm²/Vs. Organic compounds that can be used as the hole-transport material for the composite material are specifically described below.

Examples of the aromatic amine compound that can be used for the composite material include N,N-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), N,N-bis{4-[bis(3-methylphenyl)amino]phenyl}-N,N′-diphenyl-(1,1′-biphenyl)-4,4′-diamine (abbreviation: DNTPD), and 1,3,5-tris[N-(4-diphenylaminophenyl)-N-phenylamino]benzene (abbreviation: DPA3B). Specific examples of the carbazole derivative include 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 4,4′-di(N-carbazolyl)biphenyl (abbreviation: CBP), 1,3,5-tris[4-(N-carbazolyl)phenyl]benzene (abbreviation: TCPB), 9-[4-(10-phenyl-9-anthracenyl)phenyl]-9H-carbazole (abbreviation: CzPA), and 1,4-bis[4-(N-carbazolyl)phenyl]-2,3,5,6-tetraphenylbenzene. Examples of the aromatic hydrocarbon include 2-tert-butyl-9,10-di(2-naphthyl)anthracene (abbreviation: t-BuDNA), 2-tert-butyl-9,10-di(1-naphthyl)anthracene, 9,10-bis(3,5-diphenylphenyl)anthracene (abbreviation: DPPA), 2-tert-butyl-9,10-bis(4-phenylphenyl)anthracene (abbreviation: t-BuDBA), 9,10-di(2-naphthyl)anthracene (abbreviation: DNA), 9,10-diphenylanthracene (abbreviation: DPAnth), 2-tert-butylanthracene (abbreviation: t-BuAnth), 9,10-bis(4-methyl-1-naphthyl)anthracene (abbreviation: DMNA), 2-tert-butyl-9,10-bis[2-(1-naphthyl)phenyl]anthracene, 9,10-bis[2-(1-naphthyl)phenyl]anthracene, 2,3,6,7-tetramethyl-9,10-di(1-naphthyl)anthracene, 2,3,6,7-tetramethyl-9,10-di(2-naphthyl)anthracene, 9,9′-bianthryl, 10,10′-diphenyl-9,9′-bianthryl, 10,10′-bis(2-phenylphenyl)-9,9′-bianthryl, 10,10′-bis[(2,3,4,5,6-pentaphenyl)phenyl]-9,9′-bianthryl, anthracene, tetracene, rubrene, perylene, and 2,5,8,11-tetra(tert-butyl)perylene. Other examples include pentacene and coronene. The aromatic hydrocarbon may have a vinyl skeleton. Examples of the aromatic hydrocarbon having a vinyl group include 4,4′-bis(2,2-diphenylvinyl)biphenyl (abbreviation: DPVBi) and 9,10-bis[4-(2,2-diphenylvinyl)phenyl]anthracene (abbreviation: DPVPA). Note that the organic compound of one embodiment of the present invention can also be used.

A high molecular compound such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide] (abbreviation: PTPDMA), or poly[N,N-bis(4-butylphenyl)-N,N-bis(phenyl)benzidine] (abbreviation: Poly-TPD) can also be used.

The hole-transport material used for the composite material further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound preferably has an N,N-bis(4-biphenyl)amino group because a light-emitting device having a long lifetime can be fabricated. Specific examples of such an organic compound include N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), NN-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: (αNBA1BP), 4,4′-bis(1-naphthyl)triphenylamine (abbreviation: (αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(1,1′-biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(4-biphenylyl)-9,9′-spirobi[9H-fluoren]-2-amine (abbreviation: BBASF), N,N-bis(1,1′-biphenyl-4-yl)-9,9′-spirobi[9H-fluoren]-4-amine (abbreviation: BBASF(4)), N-(1,1′-biphenyl-2-yl)-N-(9,9-dimethyl-9H-fluoren-2-yl)-9,9′-spirobi[9H-fluoren]-4-amine (abbreviation: oFBiSF), N-(4-biphenyl)-N-(dibenzofuran-4-yl)-9,9-dimethyl-9H-fluoren-2-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]spiro-9,9′-bifluoren-2-amine (abbreviation: PCBASF), N-(1,1′-biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Further preferably, the hole-transport material used for the composite material has a relatively deep HOMO level higher than or equal to −5.7 eV and lower than or equal to −5.4 eV. When the hole-transport material used for the composite material has a relatively deep HOMO level, holes can be easily injected into the hole-transport layer 112 to easily provide a light-emitting device having a long lifetime. In addition, when the hole-transport material used for the composite material has a relatively deep HOMO level, induction of holes can be inhibited properly so that a light-emitting device having a longer lifetime can be easily obtained.

Note that mixing the above composite material with a fluoride of an alkali metal or an alkaline earth metal (the proportion of fluorine atoms in the layer is preferably greater than or equal to 20%) can lower the refractive index of the layer. This also enables a layer with a low refractive index to be formed in the EL layer 103, improving the external quantum efficiency of the light-emitting device.

The formation of the hole-injection layer 111 can improve the hole-injection property, offering the light-emitting device with a low driving voltage.

The hole-transport layer 112 contains a hole-transport material. The hole-transport material preferably has a hole mobility higher than or equal to 1×10⁻⁶ cm²/Vs.

Examples of the hole-transport material include compounds having an aromatic amine skeleton, such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]spiro-9,9′-bifluoren-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(1,1′-biphenyl-3-yl)-3,3′-bi-9H-carbazole (abbreviation: BismBPCz), 9-(1,1′-biphenyl-3-yl)-9′-(1,1′-biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: PNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′: 3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the hole-transport material used for the composite material for the hole-injection layer 111 can also be suitably used as the material included in the hole-transport layer 112.

The light-emitting layer 113 preferably contains the light-emitting substance and the first organic compound. The second organic compound may be further contained. The light-emitting layer 113 may additionally contain other materials. Alternatively, the light-emitting layer 113 may be a stack of two layers with different compositions. It is preferable that the first organic compound be an organic compound having an electron-transport property and the second organic compound be an organic compound having a hole-transport property.

The light-emitting substance may be a fluorescent substance, a phosphorescent substance, or a substance exhibiting thermally activated delayed fluorescence (TADF).

Examples of the material that can be used as a fluorescent substance in the light-emitting layer 113 are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N′,N′-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(1,1′-biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(1,1′-biphenyl-2-yl)-2-anthryl]-N,N,N-triphenyl-1,4-phenylenediamine (abbreviation: 2DPABPhA), 9,10-bis(1,1′-biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, NN-diphenylquinacridone (abbreviation: DPQd), rubrene, 5,12-bis(1,1′-biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Examples of the material that can be used when a phosphorescent substance is used as the light-emitting substance in the light-emitting layer 113 are as follows.

The examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]), bis(1-phenylisoquinolinato-N,C^{2′})iridium(III) acetylacetonate (abbreviation: [Ir(piq)₂(acac)]), (3,7-diethyl-4,6-nonanedionato-κO4,κO6)bis[2,4-dimethyl-6-[7-(1-methylethyl)-1-isoquinolinyl-κN]phenyl-κC]iridium(III), and (3,7-diethyl-4,6-nonanedionato-K04,K06)bis[2,4-dimethyl-6-[5-(1-methylethyl)-2-quinolinyl-κN]phenyl-κC]iridium(III); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds have an emission peak in the wavelength range of 600 nm to 700 nm. Organometallic iridium complexes having a pyrazine skeleton can provide red light emission with favorable chromaticity. Note that other known red phosphorescent substances can also be used.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-KC}iridium(III) (abbreviation: [Ir(mpptz-dmp)₃]) or tris(5-methyl-3,4-diphenyl-4H-1,2,4-triazolato)iridium(III) (abbreviation: [Ir(Mptz)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[l-(2,6-diisopropylphenyl)-2-phenyl-1H-imidazole]iridium(III) (abbreviation: [Ir(iPrpmi)₃]), tris[3-(2,6-dimethylphenyl)-7-methylimidazo[1,2-f]phenanthridinato]iridium(III) (abbreviation: [Ir(dmpimpt-Me)₃]), or tris(2-[1-{2,6-bis(1-methylethyl)phenyl}-1H-imidazol-2-yl-κN3]-4-cyanophenyl-κC) (abbreviation: CNImIr); an organometallic complex having a benzimidazolidene skeleton, such as tris[(6-tert-butyl-3-phenyl-2H-imidazo[4,5-b]pyrazin-1-yl-κC2)phenyl-κC]iridium(III) (abbreviation: [Ir(cb)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 440 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C^{2′})iridium(III) acetylacetonate (abbreviation: [Ir(pq)₂(acac)]), [2-d3-methyl-8-(2-pyridinyl-κN)benzofuro[2,3-b]pyridine-κC]bis[2-(5-d3-methyl-2-pyridinyl-κN2)phenyl-κC]iridium(III) (abbreviation: Ir(5mppy-d3)₂(mbfpypy-d3)), [2-(methyl-d3)-8-[4-(1-methylethyl-1-d)-2-pyridinyl-κN]benzofuro[2,3-b]pyridin-7-yl-κC]bis[5-(methyl-d3)-2-[5-(methyl-d3)-2-pyridinyl-κN]phenyl-κC]iridium(III) (abbreviation: Ir(5mtpy-d6)₂(mbfpypy-iPr-d4)), [2-d3-methyl-(2-pyridinyl-κN)benzofuro[2,3-b]pyridine-κC]bis[2-(2-pyridinyl-x1V)phenyl-κC]iridium(III) (abbreviation: Ir(ppy)₂(mbfpypy-d3)), [2-(4-d3-methyl-5-phenyl-2-pyridinyl-κN2)phenyl-κC]bis[2-(5-d3-methyl-2-pyridinyl-κN2)phenyl-κC]iridium(III) (abbreviation: [Ir(5mppy-d3)₂(mdppy-d3)]), [2-methyl-(2-pyridinyl-x1V)benzofuro[2,3-b]pyridine-κC]bis[2-(2-pyridinyl-κN)phenyl-κC]iridium(III) (abbreviation: [Ir(ppy)₂(mbfpypy)]), or [2-(4-methyl-5-phenyl-2-pyridinyl-κN)phenyl-κC]bis[2-(2-pyridinyl-x1V)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that emit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Examples of the TADF material include a fullerene, a derivative thereof, an acridine, a derivative thereof, and an eosin derivative. Other examples include a metal-containing porphyrin containing magnesium (Mg), zinc (Zn), cadmium (Cd), tin (Sn), platinum (Pt), indium (In), palladium (Pd), or the like. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

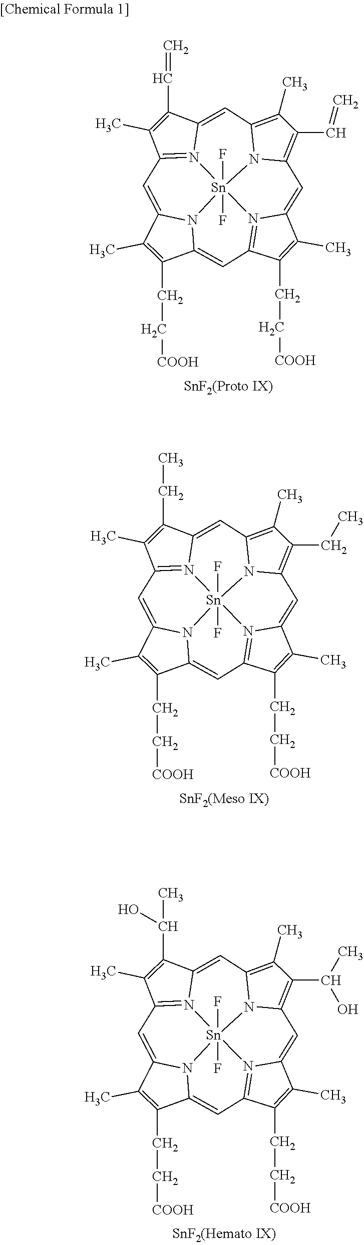

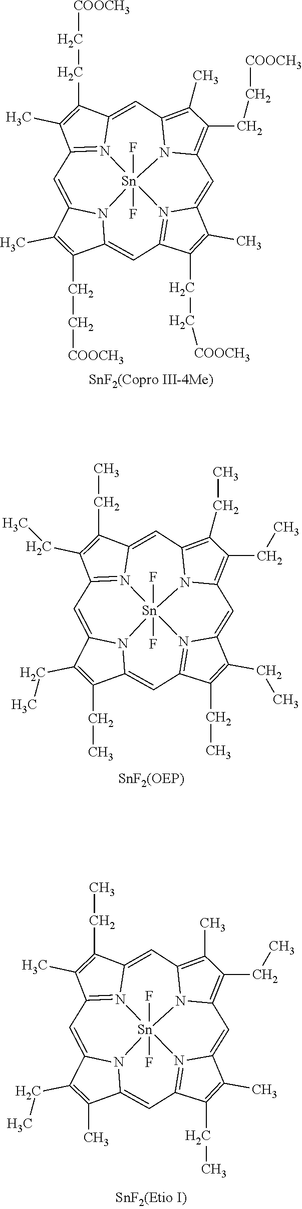

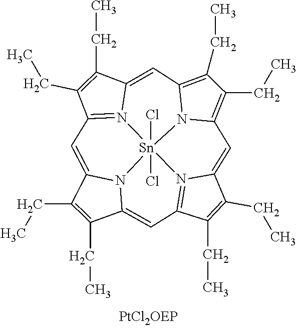

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferred because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a nitrile group or a cyano group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

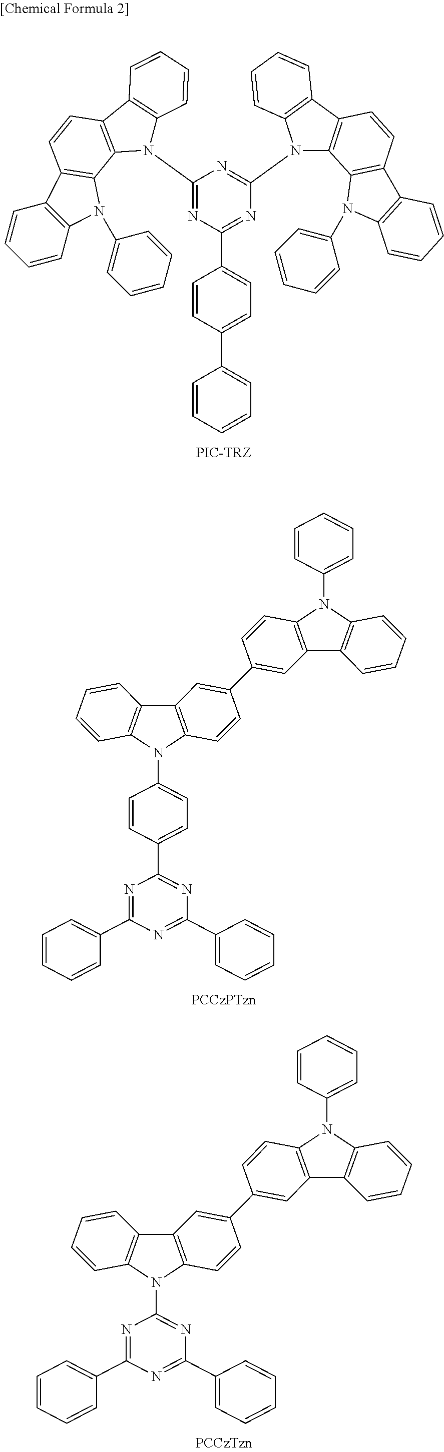 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1]

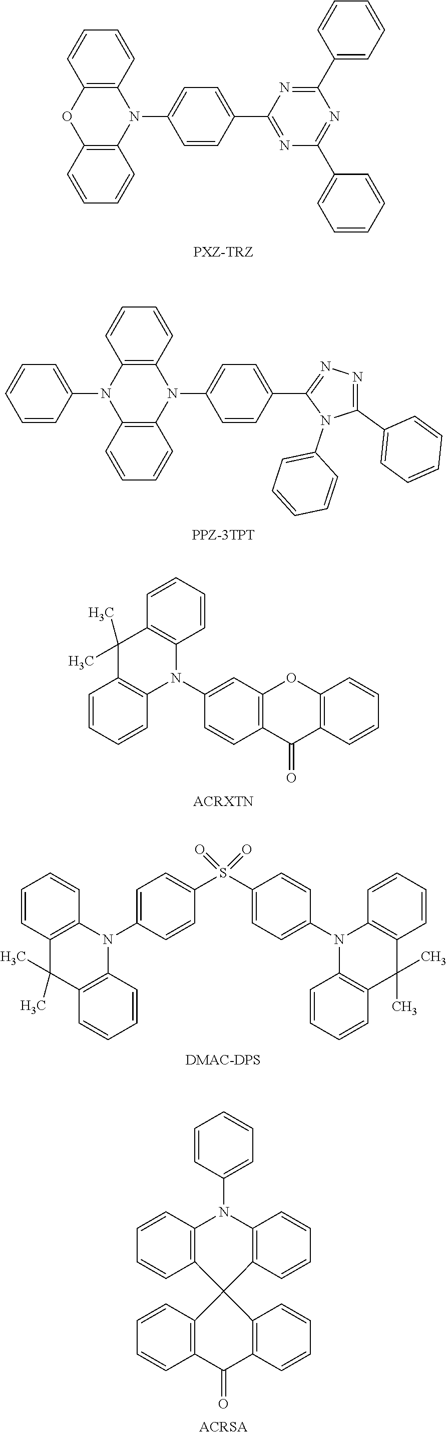 [SMILES: c1ccc(-c2nc(-c3ccccc3)nc(-c3ccc(N4c5ccccc5Oc5ccccc54)cc3)n2)cc1 ; c1ccc(-c2nnc(-c3ccc(N4c5ccccc5N(c5ccccc5)c5ccccc54)cc3)n2-c2ccccc2)cc1 ; CC1(C)c2ccccc2N(c2ccc3c(=O)c4ccccc4oc3c2)c2ccccc21 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

A TADF material that enables reversible intersystem crossing at extremely high speed and emits light in accordance with a thermal equilibrium model between a singlet excited state and a triplet excited state may be used. Since such a TADF material has an extremely short emission lifetime (excitation lifetime), an efficiency decrease of a light-emitting element in a high-luminance region can be inhibited. Specifically, a material having the following molecular structure can be used.

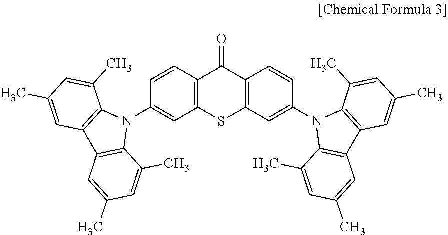

Note that a TADF material is a material having a small difference between the S1 level and the T1 level and a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the S1 level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between S1 and T1 of the TADF material is preferably smaller than or equal to 0.3 eV, further preferably smaller than or equal to 0.2 eV.

When a TADF material is used as the light-emitting substance, the Si level of the host material is preferably higher than the Si level of the TADF material. In addition, the T1 level of the host material is preferably higher than the T1 level of the TADF material.

Since a significant effect can be obtained in the case where the light-emitting substance in the light-emitting device of one embodiment of the present invention is a substance that emits blue light, one embodiment of the present invention is preferably employed for a light-emitting device containing a light-emitting substance that emits blue light.

As an electron-transport material used as the host material, for example, a metal complex such as bis(10-hydroxybenzo[h]quinolinato)beryllium(II) (abbreviation: BeBq₂), bis(2-methyl-8-quinolinolato) (4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound including a π-electron deficient heteroaromatic ring can be used. Examples of the organic compound including a π-electron deficient heteroaromatic ring include an organic compound including a heteroaromatic ring having a polyazole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), or 2-[3-(dibenzothiophen-4-yl)phenyl]-1-phenyl-1H-benzimidazole (abbreviation: mDBTBIm-II); an organic compound including a heteroaromatic ring having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 2,6-bis(4-naphthalen-1-ylphenyl)-4-[4-(3-pyridyl)phenyl]pyrimidine (abbreviation: 2,4NP-6PyPPm), 6-(1,1′-biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(1,1′-biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), 11-[(3′-dibenzothiophen-4-yl)biphenyl-3-yl]phenanthro[9′,10′:4,5]furo[2,3-b]pyrazine (abbreviation: 11mDBtBPPnfpr), 11-[(3′-dibenzothiophen-4-yl)biphenyl-4-yl]phenanthro[9′,10′:4,5]furo[2,3-b]pyrazine, 11-[(3′-(9H-carbazol-9-yl)biphenyl-3-yl]phenanthro[9′,10′:4,5]furo[2,3-b]pyrazine, 12-(9′-phenyl-3,3′-bi-9H-carbazol-9-yl)phenanthro[9′,10′:4,5]furo[2,3-b]pyrazine (abbreviation: 12PCCzPnfpr), 9-[(3′-9-phenyl-9H-carbazol-3-yl)biphenyl-4-yl]naphtho[1′,2′:4,5]furo[2,3-b]pyrazine (abbreviation: 9pmPCBPNfpr), 9-(9′-phenyl-3,3′-bi-9H-carbazol-9-yl)naphtho[1′,2′:4,5]furo[2,3-b]pyrazine (abbreviation: 9PCCzNfpr), 10-(9′-phenyl-3,3′-bi-9H-carbazol-9-yl)naphtho[1′,2′:4,5]furo[2,3-b]pyrazine (abbreviation: 10PCCzNfpr), 9-[3′-(6-phenylbenzo[b]naphtho[1,2-d]furan-8-yl)biphenyl-3-yl]naphtho[1′,2′:4,5]furo[2,3-b]pyrazine (abbreviation: 9mBnfBPNfpr), 9-{3-[6-(9,9-dimethylfluoren-2-yl)dibenzothiophen-4-yl]phenyl}naphtho[1′,2′:4,5]furo[2,3-b]pyrazine (abbreviation: 9mFDBtPNfpr), 9-[3′-(6-phenyldibenzothiophen-4-yl)biphenyl-3-yl]naphtho[1′,2′:4,5]furo[2,3-b]pyrazine (abbreviation: 9mDBtBPNfpr-02), 9-[3-(9′-phenyl-3,3′-bi-9H-carbazol-9-yl)phenyl]naphtho[1′,2′:4,5]furo[2,3-b]pyrazine (abbreviation: 9mPCCzPNfpr), 9-{3′-[2,8-diphenyldibenzothiophen-4-yl]biphenyl-3-yl}naphtho[1′,2′:4,5]furo[2,3-b]pyrazine, or 11-{3′-[2,8-diphenyldibenzothiophen-4-yl]biphenyl-3-yl}phenanthro[9′,10′:4,5]furo[2,3-b]pyrazine; an organic compound including a heteroaromatic ring having a pyridine skeleton, such as 3,5-bis[3-(9H-carbazol-9-yl)phenyl]pyridine (abbreviation: 35DCzPPy) or 1,3,5-tri[3-(3-pyridyl)phenyl]benzene (abbreviation: TmPyPB); and an organic compound including a heteroaromatic ring having a triazine skeleton, such as 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)-1,1′-biphenyl-3-yl]-4,6-diphenyl′1,3,5-triazine (abbreviation: mTpBPTzn), 9-[4-(4,6-diphenyl-1,3,5-triazin-2-yl)-2-dibenzothiophenyl]-2-phenyl-9H-carbazole (abbreviation: PCDBfTzn), or 2-[1,1′-biphenyl]-3-yl-4-phenyl-6-(8-[1,1′:4′,1″-terphenyl]-4-yl-1-dibenzofuranyl)-1,3,5-triazine (abbreviation: mBP-TPDBfTzn). Among the above materials, the organic compound including a heteroaromatic ring having a diazine skeleton, the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage.

As a hole-transport material used as the host material, an organic compound having an amine skeleton or a π-electron rich heteroaromatic ring can be used. Examples of the organic compound having an amine skeleton or a Ti-electron rich heteroaromatic ring include a compound having an aromatic amine skeleton, such as 4,4′-bis[N-(1-naphthyl)-N-phenylamino]biphenyl (abbreviation: NPB), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]spiro-9,9′-bifluoren-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), N-[4-(9-phenyl-9H-carbazol-3-yl)phenyl]-bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine (abbreviation: PCBBiSF), N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-(1,1′: 3′,1″-terphenyl-4-yl)-9,9-dimethyl-9H-fluoren-2-amine, N-[4-(9-phenyl-9H-carbazol-3-yl)phenyl]-N-(1,1′: 4′,1″-terphenyl-4-yl)-9,9-dimethyl-9H-fluoren-2-amine, N-[4-(9-phenyl-9H-carbazol-3-yl)phenyl]-N-(1,1′: 3′,1″-terphenyl-4-yl)-9,9-dimethyl-9H-fluoren-4-amine, or N-[4-(9-phenyl-9H-carbazol-3-yl)phenyl]-N-(1,1′: 4′,1″-terphenyl-4-yl)-9,9-dimethyl-9H-fluoren-4-amine; a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the hole-transport material that can be used for the hole-transport layer 112 can also be used as the hole-transport material of the host.

Note that by mixing the electron-transport material with the hole-transport material, the transport property of the light-emitting layer 113 can be easily adjusted and a recombination region can be easily controlled. The TADF material can be used as the electron-transport material or the hole-transport material.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the Si level of the TADF material is preferably higher than the Si level of the fluorescent substance in order that high emission efficiency can be achieved. Furthermore, the T1 level of the TADF material is preferably higher than the Si level of the fluorescent substance. Therefore, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This case is preferable because excitation energy is transferred smoothly from the TADF material to the fluorescent substance and light emission can be obtained efficiently.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protective group around a luminophore (a skeleton which causes light emission) of the fluorescent substance. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent substance have a plurality of protective groups. The substituents having no π bond are poor in carrier transport performance; thus, the TADF material and the luminophore of the fluorescent substance can be made away from each other with little influence on carrier transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of the condensed aromatic ring or the condensed heteroaromatic ring include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is preferable because of its chemical stability. The host material preferably has a carbazole skeleton because the hole-injection and hole-transport properties are improved; further preferably, the host material has a benzocarbazole skeleton in which a benzene ring is further condensed to carbazole because the HOMO level thereof is shallower than that of carbazole by approximately 0.1 eV and thus holes enter the host material easily. In particular, the host material preferably has a dibenzocarbazole skeleton because the HOMO level thereof is shallower than that of carbazole by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)-phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho[1,2-d]furan (abbreviation: 2mBnfPPA), 9-phenyl-10-{4-(9-phenyl-9H-fluoren-9-yl)biphenyl-4′-yl}anthracene (abbreviation: FLPPA), 9-(1-naphthyl)-10-[4-(2-naphthyl)phenyl]anthracene (abbreviation: (αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)-benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), 1-[4-(10-[,1,1′-biphenyl]-4-yl-9-anthracenyl)phenyl]-2-ethyl-1H-benzimidazole (abbreviation: EtBImPBPhA), 2,9-di(1-naphthyl)-10-phenylanthracene (abbreviation: 2αN-(αNPhA), 9-(1-naphthyl)-10-[3-(1-naphthyl)phenyl]anthracene (abbreviation: αN-mαNPAnth), 9-(2-naphthyl)-10-[3-(1-naphthyl)phenyl]anthracene (abbreviation: βN-mαNPAnth, 9-(1-naphthyl)-10-[4-(1-naphthyl)phenyl]anthracene (abbreviation: αN-αNPAnth), 9-(2-naphthyl)-10-[4-(2-naphthyl)phenyl]anthracene (abbreviation: βN-βNPAnth), and 2-(1-naphthyl)-9-(2-naphthyl)-10-phenylanthracene (abbreviation: 2αN-βNPhA). In particular, CzPA, cgDBCzPA, 2mBnfPPA, and PCzPA exhibit excellent properties and thus are preferably selected.

Note that a phosphorescent substance can be used as part of the mixed material. When a fluorescent substance is used as the light-emitting substance, a phosphorescent substance can be used as an energy donor for supplying excitation energy to the fluorescent substance.

An exciplex may be formed of the mixed materials. The mixed materials are preferably selected so as to form an exciplex that exhibits light emission overlapping with the wavelength of a lowest-energy-side absorption band of the light-emitting substance, in which case energy can be transferred smoothly and light emission can be obtained efficiently. The use of such a structure is also preferable because the driving voltage is reduced.

Note that at least one of the materials forming an exciplex may be a phosphorescent substance. In this case, triplet excitation energy can be efficiently converted into singlet excitation energy by reverse intersystem crossing.

A combination of an electron-transport material and a hole-transport material whose HOMO level is higher than or equal to the HOMO level of the electron-transport material is preferable for forming an exciplex efficiently. In addition, the LUMO level of the hole-transport material is preferably higher than or equal to the LUMO level of the electron-transport material. Note that the LUMO levels and the HOMO levels of the materials can be derived from the electrochemical characteristics (the reduction potentials and the oxidation potentials) of the materials that are measured by cyclic voltammetry (CV).

The formation of an exciplex can be confirmed by a phenomenon in which the emission spectrum of a mixed film in which the hole-transport material and the electron-transport material are mixed is shifted to a longer wavelength than the emission spectrum of each of the materials (or has another peak on the longer wavelength side) observed in comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed in comparison of transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed in comparison of the transient EL of the hole-transport material, the transient EL of the electron-transport material, and the transient EL of the mixed film of these materials.

In the case where a hole-blocking layer is provided, the hole-blocking layer is in contact with the light-emitting layer 113, and is formed to contain an organic compound having an electron-transport property and being capable of blocking holes. As the organic compound contained in the hole-blocking layer, a material having a high electron-transport property, a low hole-transport property, and a deep HOMO level is suitably used. Specifically, it is preferable to use a substance having a deeper HOMO level than the material contained in the light-emitting layer 113 by 0.5 eV or more and having an electron mobility of 1×10⁻⁶ cm²/Vs or higher when the square root of the electric field strength [V/cm] is 600.

In particular, 2-{3-[3-(N-phenyl-9H-carbazol-3-yl)-9H-carbazol-9-yl]phenyl}dibenzo[f,h]quinoxaline (abbreviation: 2mPCCzPDBq), 2-{3-[2-(N-phenyl-9H-carbazol-3-yl)-9H-carbazol-9-yl]phenyl}dibenzo[f,h]quinoxaline (abbreviation: 2mPCCzPDBq-02), 2-{3-[3-(N-phenyl-9H-carbazol-2-yl)-9H-carbazol-9-yl]phenyl}dibenzo[f,h]quinoxaline (abbreviation: 2mPCCzPDBq-03), 2-{3-[3-(N-(3,5-di-tert-butylphenyl-9H-carbazol-3-yl)-9H-carbazol-9-yl]phenyl}dibenzo[f,h]quinoxaline, 9-[3-(4,6-diphenyl-1,3,5-triazin-2-yl)phenyl]-9′-phenyl-3,3′-bi-9H-carbazole (abbreviation: mPCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-(4,6-diphenyl-1,3,5-triazin-2-yl)-9′-phenyl-3,3′-bi-9H-carbazole (abbreviation: PCCzTzn(CzT)), 9-[3-(4,6-diphenyl-pyrimidin-2-yl)phenyl]-9′-phenyl-3,3′-bi-9H-carbazole (abbreviation: 2PCCzPPm), 9-(4,6-diphenyl-pyrimidin-2-yl)-9′-phenyl-3,3′-bi-9H-carbazole (abbreviation: 2PCCzPm), 4-[2-(N-phenyl-9H-carbazol-3-yl)-9H-carbazol-9-yl]benzofuro[3,2-d]pyrimidine (abbreviation: 4PCCzBfpm-02), 4-{3-[3-(N-phenyl-9H-carbazol-3-yl)-9H-carbazol-9-yl]phenyl}benzo[h]quinazoline, and 9-[3-(2,6-diphenyl-pyridin-4-yl)phenyl]-9′-phenyl-3,3′-bi-9H-carbazole are preferable because of their high heat resistance.

In the case of using other materials for the hole-blocking layer, an organic compound having a deeper HOMO level than the material contained in the light-emitting layer 113 is selected from materials that can be used for a hole-transport layer, which will be described later.

For the electron-transport layer 114, it is preferable to use an organic compound having an electron-transport property that is a substance with an electron mobility of 1×10⁻⁶ cm²/Vs or higher when the square root of the electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton.

Specific examples of the organic compound including a π-electron deficient heteroaromatic ring that can be used for the above electron-transport layer include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound including a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), 3,5-bis[3-(9H-carbazol-9-yl)phenyl]pyridine (abbreviation: 35DCzPPy), bathophenanthroline (abbreviation: Bphen), bathocuproine (abbreviation: BCP), or 2,9-di(naphthalen-2-yl)-4,7-diphenyl-1,10-phenanthroline (abbreviation: NBphen); an organic compound having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′: 4,5]furo[2,3-b]pyrazine (abbreviation: 9mDBtBPNfpr), 9-[(3′-dibenzothiophen-4-yl)biphenyl-4-yl]naphtho[1′,2′: 4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(1,1′-biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(1,1′-biphenyl-3-yl)]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)₂Py), 2,2′-(pyridine-2,6-diyl)bis{4-[4-(2-naphthyl)phenyl]-6-phenylpyrimidine} (abbreviation: 2,6(NP-PPm)₂Py), 6-(1,1′-biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(1,1′-biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), 8-(1,1′: 4′,1″-terphenyl-3-yl)-4-[3-(dibenzothiophen-4-yl)phenyl]-[1]benzofuro[3,2-d]pyrimidine (abbreviation: 8mpTP-4mDBtPBfpm), 4,8-bis[3-(dibenzofuran-4-yl)phenyl]benzofuro[3,2-d]pyrimidine, 8-(1,1′: 4′,1″-terphenyl-3-yl)-4-[3-(dibenzothiophen-4-yl)biphenyl-4-yl]-benzofuro[3,2-d]pyrimidine, 4,8-bis[3-(9H-carbazol-9-yl)phenyl]-[1]benzofuro[3,2-d]pyrimidine (abbreviation: 4,8mCzP2Bfpm), 8-(1,1′: 4′,1″-terphenyl-3-yl)-4-[3-(9-phenyl-9H-carbazol-3-yl)phenyl]-benzofuro[3,2-d]pyrimidine, 8-(1,1′-biphenyl-4-yl)-4-[3-(9-phenyl-9H-carbazol-3-yl)biphenyl-3-yl]-benzofuro[3,2-d]pyrimidine, 8-(1,1′-biphenyl-4-yl)-4-{3-[2-(N-phenyl-9H-carbazol-3-yl)-9H-carbazol-9-yl]phenyl}benzofuro[3,2-d]pyrimidine, 8-phenyl-4-{3-[2-(N-phenyl-9H-carbazol-3-yl)-9H-carbazol-9-yl]phenyl}benzofuro[3,2-d]pyrimidine, or 8-(1,1′-biphenyl-4-yl)-4-(3,5-di-9H-carbazol-9-yl-phenyl)benzofuro[3,2-d]pyrimidine; and an organic compound having a triazine skeleton, such as 2-[3′-(9,9-dimethyl-9H-fluoren-2-yl)-1,1′-biphenyl-3-yl]-4,6-diphenyl-1,3,5-triazine (abbreviation: mFBPTzn), 2-[(1,1′-biphenyl)-4-yl]-4-phenyl-6-[9,9′-spirobi(9H-fluoren)-2-yl]-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-1,1′-biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tri s(3′-(pyridin-3-yl)biphenyl-3-yl)-1,3,5-triazine (abbreviation: TmPPPyTz), 2-[3-(2,6-dimethyl-3-pyridyl)-5-(9-phenanthryl)phenyl]-4,6-diphenyl-1,3,5-triazine (abbreviation: mPn-mDMePyPTzn), 11-(4-[1,1′-biphenyl]-4-yl-6-phenyl-1,3,5-triazin-2-yl)-11,12-dihydro-12-phenyl-indolo[2,3-a]carbazole (abbreviation: BP-Icz(II)Tzn), 2-[3′-(triphenylen-2-yl)-1,1′-biphenyl-3-yl]-4,6-diphenyl-1,3,5-triazine (abbreviation: mTpBPTzn), 9-[4-(4,6-diphenyl-1,3,5-triazin-2-yl)-2-dibenzothiophenyl]-2-phenyl-9H-carbazole (abbreviation: PCDBfTzn), or 2-[1,1′-biphenyl]-3-yl-4-phenyl-6-(8-[1,1′: 4′,1″-terphenyl]-4-yl-1-dibenzofuranyl)-1,3,5-triazine (abbreviation: mBP-TPDBfTzn). Among the above materials, the organic compound including a heteroaromatic ring having a diazine skeleton, the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have high electron-transport properties to contribute to a reduction in driving voltage.

Note that the electron-transport layer 114 having this structure also serves as the electron-injection layer 115 in some cases.

A layer containing an alkali metal, an alkaline earth metal, a compound thereof, or a complex thereof such as lithium fluoride (LiF), cesium fluoride (CsF), calcium fluoride (CaF₂), or 8-hydroxyquinolinato-lithium (abbreviation: Liq) is preferably provided as the electron-injection layer 115 between the electron-transport layer 114 and the common electrode (cathode) 102. Alternatively, a film formed by co-evaporation of ytterbium (Yb) and lithium is preferable. As the electron-injection layer 115, an electride or a layer that is formed using a substance having an electron-transport property and that contains an alkali metal, an alkaline earth metal, or a compound thereof may be used. Examples of the electride include a substance in which electrons are added at high concentration to calcium oxide-aluminum oxide.

Note that as the electron-injection layer 115, it is possible to use a layer that contains a substance having an electron-transport property (preferably an organic compound having a bipyridine skeleton) and contains a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 and Group 2 of the periodic table, such as alkali metals (e.g., lithium (Li) and cesium (Cs)), magnesium (Mg), calcium (Ca), and strontium (Sr), alloys containing these elements (e.g., MgAg and AlLi), rare earth metals such as europium (Eu) and ytterbium (Yb), and alloys containing these rare earth metals. However, when the electron-injection layer is provided between the cathode and the electron-transport layer, any of a variety of conductive materials such as Al, Ag, ITO, and indium oxide-tin oxide containing silicon or silicon oxide can be used for the cathode regardless of the work function.

Films of these conductive materials can be deposited by a dry process such as a vacuum evaporation method or a sputtering method, an ink-jet method, a spin coating method, or the like. Alternatively, the films may be formed by a wet process using a sol-gel method or a wet process using a paste of a metal material.

A variety of methods can be used as a method for forming the EL layer 103 regardless of whether it is a dry process or a wet process. For example, a vacuum evaporation method, a gravure printing method, an offset printing method, a screen printing method, an ink-jet method, a spin coating method, or the like may be used.

Different deposition methods may be used to form the electrodes or the layers described above.

The structure of the layers provided between the anode and the cathode is not limited to the above-described structure. However, a light-emitting region where holes and electrons recombine is preferably positioned away from the anode and the cathode so as to inhibit quenching due to the proximity of the light-emitting region and a metal used for electrodes or carrier-injection layers.

Furthermore, in order to inhibit energy transfer from an exciton generated in the light-emitting layer, it is preferable to form the hole-transport layer or the electron-transport layer that is in contact with the light-emitting layer 113, particularly a carrier-transport layer closer to the recombination region in the light-emitting layer 113, using the light-emitting material of the light-emitting layer or a substance having a wider band gap than the light-emitting material contained in the light-emitting layer.

The structure of this embodiment can be used in combination with any of the structures of the other embodiments as appropriate.

### Embodiment 3

In this embodiment, a light-emitting apparatus fabricated using the light-emitting device described in Embodiment 1 and Embodiment 2 will be described with reference to FIG. 3A and FIG. 3B. Note that FIG. 3A is a top view of the light-emitting apparatus and FIG. 3B is a cross-sectional view taken along the dashed-dotted line A-B and the dashed-dotted line C-D in FIG. 3A. This light-emitting apparatus includes a driver circuit portion (source line driver circuit) 601, a pixel portion 602, and a driver circuit portion (gate line driver circuit) 603, which are to control light emission of a light-emitting device and illustrated with dotted lines. Reference numeral 604 denotes a sealing substrate; 605, a sealing material; and 607, a space surrounded by the sealing material 605.

A lead wiring 608 is a wiring for transmitting signals to be input to the source line driver circuit 601 and the gate line driver circuit 603 and receives a video signal, a clock signal, a start signal, a reset signal, or the like from an FPC (flexible printed circuit) 609 serving as an external input terminal. Although only the FPC is illustrated here, a printed wiring board (PWB) may be attached to the FPC. The light-emitting apparatus in this specification includes, in its category, not only the light-emitting apparatus itself but also the light-emitting apparatus provided with the FPC or the PWB.

Next, a cross-sectional structure will be described with reference to FIG. 3B. The driver circuit portions and the pixel portion are formed over an element substrate 610; here, the source line driver circuit 601, which is a driver circuit portion, and one pixel in the pixel portion 602 are illustrated.

The element substrate 610 is formed using a substrate containing glass, quartz, an organic resin, a metal, an alloy, a semiconductor, or the like or a plastic substrate formed of FRP (Fiber Reinforced Plastics), PVF (polyvinyl fluoride), polyester, an acrylic resin, or the like.

The structure of transistors used in pixels or driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and an amorphous semiconductor or a semiconductor having crystallinity (a microcrystalline semiconductor, a polycrystalline semiconductor, a single crystal semiconductor, or a semiconductor partly including crystal regions) may be used. A semiconductor having crystallinity is preferably used because deterioration of the transistor characteristics can be inhibited.

Here, an oxide semiconductor is preferably used for semiconductor devices such as transistors provided in the pixels or driver circuits described above and transistors used for touch sensors described later, for example. In particular, an oxide semiconductor having a wider band gap than silicon is preferably used. When an oxide semiconductor having a wider band gap than silicon is used, the off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and having no grain boundary between adjacent crystal parts.

The use of such materials for the semiconductor layer makes it possible to provide a highly reliable transistor in which a change in the electrical characteristics is inhibited.

Charge accumulated in a capacitor through a transistor including the above-described semiconductor layer can be held for a long time because of the low off-state current of the transistor. When such a transistor is used in a pixel, operation of a driver circuit can be stopped while a gray scale of an image displayed on each display region is maintained. As a result, an electronic appliance with extremely low power consumption can be obtained.

For stable characteristics of the transistor and the like, a base film is preferably provided. The base film can be formed with a single layer or stacked layers using an inorganic insulating film such as a silicon oxide film, a silicon nitride film, a silicon oxynitride film, or a silicon nitride oxide film. The base film can be formed by a sputtering method, a CVD (Chemical Vapor Deposition) method (e.g., a plasma CVD method, a thermal CVD method, or an MOCVD (Metal Organic CVD) method), an ALD (Atomic Layer Deposition) method, a coating method, a printing method, or the like. Note that the base film is not necessarily provided when not needed.

Note that an FET 623 is illustrated as a transistor formed in the driver circuit portion 601. The driver circuit may be formed with any of a variety of circuits such as a CMOS circuit, a PMOS circuit, or an NMOS circuit. Although a driver-integrated type in which the driver circuit is formed over the substrate is described in this embodiment, the driver circuit is not necessarily formed over the substrate, and the driver circuit can be formed outside, not over the substrate.

The pixel portion 602 includes a plurality of pixels including a switching FET 611, a current controlling FET 612, and a first electrode 613 electrically connected to a drain of the current controlling FET 612; however, without being limited thereto, a pixel portion in which three or more FETs and a capacitor are combined may be employed.

Note that an insulator 614 is formed to cover an end portion of the first electrode 613. Here, the insulator 614 can be formed using a positive photosensitive acrylic resin film.

In order to improve the coverage with an EL layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). As the insulator 614, either a negative photosensitive resin or a positive photosensitive resin can be used.

An EL layer 616 and a second electrode 617 are formed over the first electrode 613. Here, the first electrode 613 functions as an anode. A material having a high work function is desirably used as a material that can be used for the anode. For example, a single-layer film of an ITO film, an indium tin oxide film containing silicon, an indium oxide film containing zinc oxide at 2 to 20 wt %, a titanium nitride film, a chromium film, a tungsten film, a Zn film, a Pt film, or the like, a stack with a film containing silver as its main component, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The EL layer 616 is formed by any of a variety of methods such as an evaporation method using an evaporation mask, an ink-jet method, and a spin coating method. The EL layer 616 has the structure described in Embodiment 1 and Embodiment 2.

As a material used for the second electrode 617, which is formed over the EL layer 616, a material having a low work function (e.g., Al, Mg, Li, and Ca, or an alloy or a compound thereof, such as MgAg, MgIn, and AlLi) is preferably used. In the case where light generated in the EL layer 616 passes through the second electrode 617, a stack of a thin metal film or alloy film and a transparent conductive film (e.g., ITO, indium oxide containing zinc oxide at 2 to 20 wt %, an indium tin oxide containing silicon, or zinc oxide (ZnO)) is preferably used for the second electrode 617.

Note that the light-emitting device is formed with the first electrode 613, the EL layer 616, and the second electrode 617. The light-emitting device is the light-emitting device described in Embodiment 1 and Embodiment 2. In the light-emitting apparatus of this embodiment, the pixel portion, which includes a plurality of light-emitting devices, may include both the light-emitting device described in Embodiment 1 and Embodiment 2 and a light-emitting device having another structure. In that case, in the light-emitting apparatus of one embodiment of the present invention, a common hole-transport layer can be used for light-emitting devices that emit light with different wavelengths, allowing the light-emitting apparatus to be manufactured in a simple process at low costs.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 is filled with a filler, and may be filled with an inert gas (such as nitrogen or argon) or the sealing material. It is preferable that the sealing substrate be provided with a depressed portion and a drying agent be provided in the depressed portion, in which case deterioration due to influence of moisture can be inhibited.

An epoxy-based resin or glass frit is preferably used for the sealing material 605. It is desirable that such a material transmit moisture or oxygen as little as possible. As the sealing substrate 604, a glass substrate, a quartz substrate, or a plastic substrate formed of FRP (Fiber Reinforced Plastics), PVF (polyvinyl fluoride), polyester, an acrylic resin, or the like can be used.

Although not illustrated in FIG. 3A and FIG. 3B, a protective film may be provided over the cathode. As the protective film, an organic resin film or an inorganic insulating film is formed. The protective film may be formed so as to cover an exposed portion of the sealing material 605. The protective film can be provided so as to cover the surfaces and side surfaces of the pair of substrates and the exposed side surfaces of a sealing layer, an insulating layer, and the like.

The protective film can be formed using a material that does not easily transmit an impurity such as water. Thus, diffusion of an impurity such as water from the outside into the inside can be effectively inhibited.

As a material of the protective film, an oxide, a nitride, a fluoride, a sulfide, a ternary compound, a metal, a polymer, or the like can be used. For example, a material containing aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, or the like; a material containing aluminum nitride, hafnium nitride, silicon nitride, tantalum nitride, titanium nitride, niobium nitride, molybdenum nitride, zirconium nitride, gallium nitride, or the like; or a material containing a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like can be used.

The protective film is preferably formed using a deposition method with favorable step coverage. One of such methods is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the light-emitting apparatus fabricated using the light-emitting device described in Embodiment 1 and Embodiment 2 can be obtained.

The light-emitting apparatus in this embodiment is fabricated using the light-emitting device described in Embodiment 1 and Embodiment 2 and thus can have excellent characteristics. Specifically, since the light-emitting device described in Embodiment 1 and Embodiment 2 has high emission efficiency, the light-emitting apparatus can achieve low power consumption. In addition, the light-emitting apparatus can have high display quality.

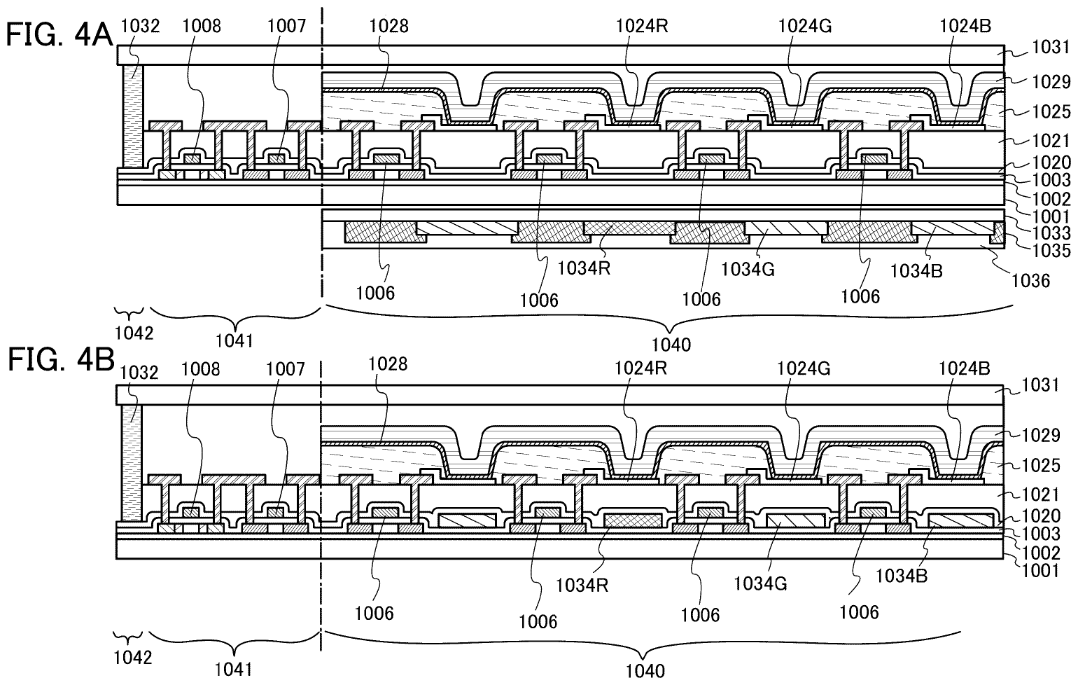

FIG. 4A and FIG. 4B each illustrate an example of a light-emitting apparatus that includes coloring layers (color filters) and the like to improve color purity. FIG. 4A illustrates a substrate 1001, a base insulating film 1002, a gate insulating film 1003, gate electrodes 1006, 1007, and 1008, a first interlayer insulating film 1020, a second interlayer insulating film 1021, a peripheral portion 1042, a pixel portion 1040, a driver circuit portion 1041, anodes 1024R, 1024G, and 1024B of light-emitting devices, a partition 1025, an EL layer 1028, a common electrode (cathode) 1029 of the light-emitting devices, a sealing substrate 1031, a sealing material 1032, and the like.

In FIG. 4A, coloring layers (a red coloring layer 1034R, a green coloring layer 1034G, and a blue coloring layer 1034B) are provided on a transparent base material 1033. A black matrix 1035 may be additionally provided. The transparent base material 1033 provided with the coloring layers and the black matrix is aligned and fixed to the substrate 1001. Note that the coloring layers and the black matrix 1035 are covered with an overcoat layer 1036.

FIG. 4B illustrates an example in which the coloring layers (the red coloring layer 1034R, the green coloring layer 1034G, and the blue coloring layer 1034B) are formed between the gate insulating film 1003 and the first interlayer insulating film 1020. As in the structure, the coloring layers may be provided between the substrate 1001 and the sealing substrate 1031.

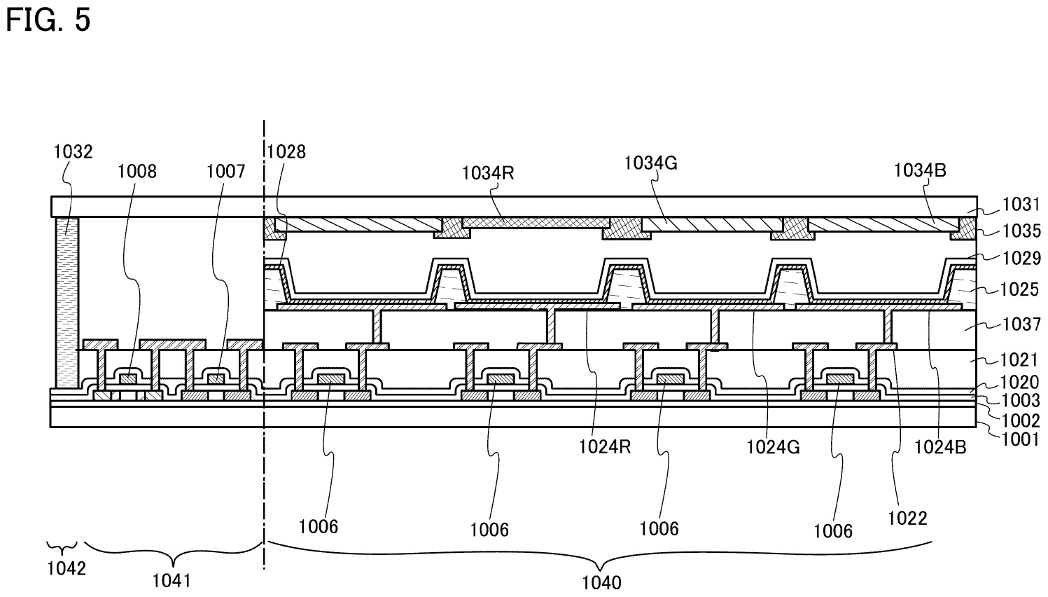

The above-described light-emitting apparatus has a structure in which light is extracted from the substrate 1001 side where FETs are formed (a bottom-emission structure), but may have a structure in which light is extracted from the sealing substrate 1031 side (a top-emission structure). FIG. 5 is a cross-sectional view of a light-emitting apparatus having a top-emission structure. In this case, a substrate that does not transmit light can be used as the substrate 1001. The process up to the step of forming a connection electrode that connects the FET and the anode of the light-emitting device is performed in a manner similar to that of the light-emitting apparatus having a bottom-emission structure. Then, a third interlayer insulating film 1037 is formed to cover an electrode 1022. This insulating film may have a planarization function. The third interlayer insulating film 1037 can be formed using a material similar to that for the second interlayer insulating film, and can alternatively be formed using any of other known materials.

The anodes 1024R, 1024G, and 1024B of the light-emitting devices each serve as an anode here, but may serve as a cathode. Furthermore, in the case of a light-emitting apparatus having a top-emission structure as illustrated in FIG. 5, the anodes are preferably reflective electrodes. The EL layer 1028 is formed to have a structure similar to the structure of the EL layer 103 described in Embodiment 1.

In the case of a top-emission structure as illustrated in FIG. 5, sealing can be performed with the sealing substrate 1031 on which the coloring layers (the red coloring layer 1034R, the green coloring layer 1034G, and the blue coloring layer 1034B) are provided. The sealing substrate 1031 may be provided with the black matrix 1035 that is positioned between pixels. The coloring layers (the red coloring layer 1034R, the green coloring layer 1034G, and the blue coloring layer 1034B) or the black matrix may be covered with the overcoat layer (not illustrated). Note that a light-transmitting substrate is used as the sealing substrate 1031.

In the light-emitting apparatus having a top-emission structure, a microcavity structure can be suitably employed. A light-emitting device with a microcavity structure is formed with the use of an electrode including a reflective electrode as one electrode and a transflective electrode as the other electrode. At least an EL layer is provided between the reflective electrode and the transflective electrode, and the EL layer includes at least a light-emitting layer serving as a light-emitting region.

Note that the reflective electrode has a visible light reflectivity of 40% to 100%, preferably 70% to 100%, and a resistivity of 1×10⁻² Ωcm or lower. In addition, the transflective electrode has a visible light reflectivity of 20% to 80%, preferably 40% to 70%, and a resistivity of 1×10⁻² Ωcm or lower.

Light emitted from the light-emitting layer included in the EL layer is reflected and resonated by the reflective electrode and the transflective electrode.

In the light-emitting device, by changing the thickness of the transparent conductive film, the composite material, the carrier-transport material, or the like, the optical path length between the reflective electrode and the transflective electrode can be changed. Thus, light with a wavelength that is resonated between the reflective electrode and the transflective electrode can be intensified while light with a wavelength that is not resonated therebetween can be attenuated.

Note that light that is reflected back by the reflective electrode (first reflected light) considerably interferes with light that directly enters the transflective electrode from the light-emitting layer (first incident light). For this reason, the optical path length between the reflective electrode and the light-emitting layer is preferably adjusted to (2n−1)λ/4 (n is a natural number of 1 or larger and λ is a wavelength of light to be amplified). By adjusting the optical path length, the phases of the first reflected light and the first incident light can be aligned with each other and the light emitted from the light-emitting layer can be further amplified.

Note that in the above structure, the EL layer may include a plurality of light-emitting layers or may include a single light-emitting layer; for example, in combination with the structure of the above-described tandem light-emitting device, a plurality of EL layers each including a single or a plurality of light-emitting layer(s) may be provided in one light-emitting device with a charge-generation layer interposed between the EL layers.

With the microcavity structure, emission intensity with a specific wavelength in the front direction can be increased, whereby power consumption can be reduced. Note that in the case of a light-emitting apparatus that displays a video with subpixels of four colors, red, yellow, green, and blue, the light-emitting apparatus can have excellent characteristics because the luminance can be increased owing to yellow light emission and each subpixel can employ a microcavity structure suitable for wavelengths of the corresponding color.

The light-emitting apparatus in this embodiment is fabricated using the light-emitting device described in Embodiment 1 and Embodiment 2 and thus can have excellent characteristics. Specifically, since the light-emitting device described in Embodiment 1 and Embodiment 2 has high emission efficiency, the light-emitting apparatus can achieve low power consumption. In addition, the light-emitting apparatus can have high display quality.

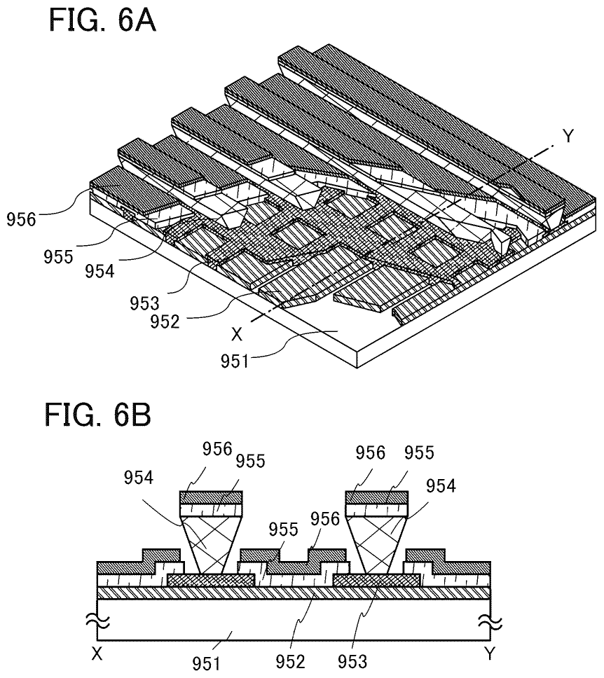

The active matrix light-emitting apparatus is described above, whereas a passive matrix light-emitting apparatus is described below. FIG. 6A and FIG. 6B illustrate a passive matrix light-emitting apparatus fabricated using the present invention. Note that FIG. 6A is a perspective view of the light-emitting apparatus, and FIG. 6B is a cross-sectional view taken along the dashed-dotted line X-Y in FIG. 6A. In FIG. 6, over a substrate 951, an EL layer 955 is provided between an electrode 952 and an electrode 956. An end portion of the electrode 952 is covered with an insulating layer 953. A partition layer 954 is provided over the insulating layer 953. The sidewalls of the partition layer 954 are aslope such that the distance between both sidewalls is gradually narrowed toward the surface of the substrate. That is, a cross section taken along the direction of the short side of the partition layer 954 is trapezoidal, and the lower side (a side that is parallel to the surface of the insulating layer 953 and is in contact with the insulating layer 953) is shorter than the upper side (a side that is parallel to the surface of the insulating layer 953 and is not in contact with the insulating layer 953). The partition layer 954 thus provided can prevent defects in the light-emitting device due to static electricity or others. The passive matrix light-emitting apparatus also includes the light-emitting device described in Embodiment 1 and Embodiment 2; thus, the light-emitting apparatus can have high display quality or low power consumption.

In the light-emitting apparatus described above, many minute light-emitting devices arranged in a matrix can each be controlled; thus, the light-emitting apparatus can be suitably used as a display apparatus for displaying images.

This embodiment can be freely combined with any of the other embodiments.

### Embodiment 4

### [Light-Emitting Apparatus]

Another example of a light-emitting apparatus of one embodiment of the present invention using the light-emitting device described in Embodiment 1 and Embodiment 2, and a fabrication method thereof will be described below.

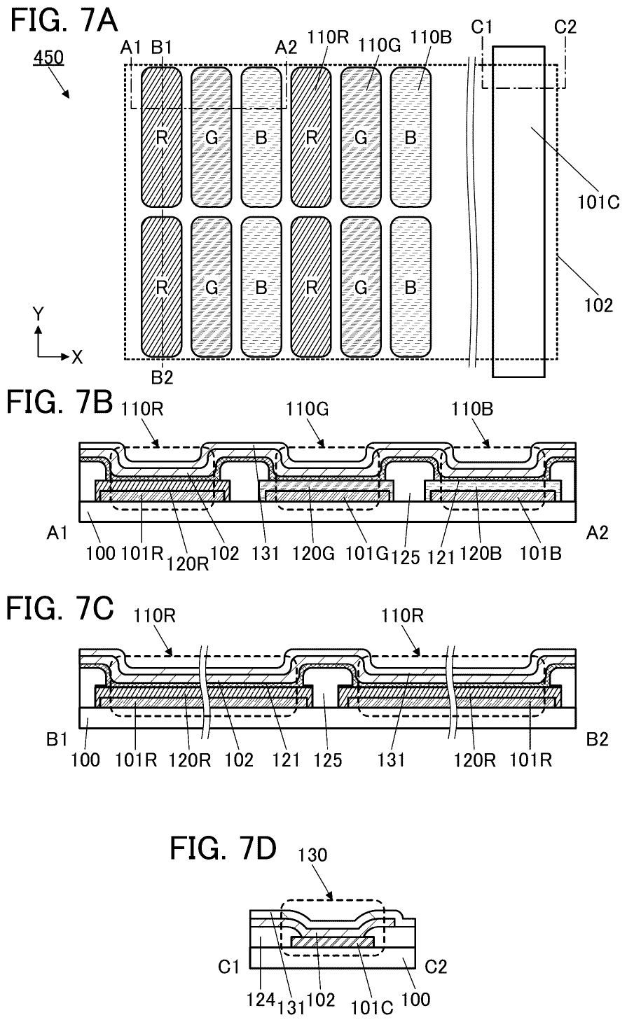

FIG. 7A is a schematic top view of a light-emitting apparatus 450 of one embodiment of the present invention. The light-emitting apparatus 450 includes a plurality of light-emitting devices 110R exhibiting red, a plurality of light-emitting devices 110G exhibiting green, and a plurality of light-emitting devices 110B exhibiting blue. In FIG. 7A, light-emitting regions of the light-emitting devices are denoted by R, G, and B to easily differentiate the light-emitting devices.

The light-emitting devices 110R, the light-emitting devices 110G, and the light-emitting devices 110B are arranged in a matrix. FIG. 7A illustrates what is called stripe arrangement, in which the light-emitting devices of the same color are arranged in one direction. Note that the arrangement method of the light-emitting devices is not limited thereto; another arrangement method such as delta arrangement, zigzag arrangement, or PenTile arrangement may also be used.

The light-emitting devices 110R, the light-emitting devices 110G, and the light-emitting devices 110B are arranged in the X direction. The light-emitting devices of the same color are arranged in the Y direction intersecting with the X direction.

The light-emitting device 110R, the light-emitting device 110G, and the light-emitting device 110B have the above-described structure.

FIG. 7B is a schematic cross-sectional view taken along the dashed-dotted line A1-A2 in FIG. 7A, and FIG. 7C is a schematic cross-sectional view taken along the dashed-dotted line B1-B2.

FIG. 7B illustrates cross sections of the light-emitting device 110R, the light-emitting device 110G, and the light-emitting device 110B. The light-emitting device 110R includes a pixel electrode (anode) 101R, a first EL layer 120R, a second EL layer 121, and the common electrode 102. The light-emitting device 110G includes a pixel electrode (anode) 101G, a first EL layer 120G, the second EL layer (electron-injection layer) 121, and the common electrode 102. The light-emitting device 110B includes a pixel electrode (anode) 101B, a first EL layer 120B, the second EL layer 121, and the common electrode 102. The second EL layer 121 and the common electrode 102 are provided to be shared by the light-emitting device 110R, the light-emitting device 110G, and the light-emitting device 110B. The second EL layer 121 can also be referred to as a common layer.

The first EL layer 120R included in the light-emitting device 110R contains at least a light-emitting organic compound that emits light with intensity in the red wavelength range. The first EL layer 120G included in the light-emitting device 110G contains at least a light-emitting organic compound that emits light with intensity in the green wavelength range. The first EL layer 120B included in the light-emitting device 110B contains at least a light-emitting organic compound that emits light with intensity in the blue wavelength range. Among the light-emitting device 110R, the light-emitting device 110G, and the light-emitting device 110B, at least the light-emitting device 110R is the light-emitting device of one embodiment of the present invention.

Each of the first EL layer 120R, the first EL layer 120G, and the first EL layer 120B includes at least a light-emitting layer, and may further include one or more of a hole-blocking layer, an electron-injection layer, an electron-transport layer, a hole-transport layer, a hole-injection layer, an electron-blocking layer, an exciton-blocking layer, and the like. The second EL layer 121 does not include the light-emitting layer. The second EL layer 121 is preferably the electron-injection layer. In the case where the second-electrode-side surfaces of the first EL layer 120R, the first EL layer 120G, and the first EL layer 120B also function as the electron-injection layers, the second EL layer 121 is not necessarily provided.

The pixel electrode (anode) 101R, the pixel electrode (anode) 101G, and the pixel electrode (anode) 101B are provided for the respective light-emitting devices. The common electrode 102 and the second EL layer 121 are each preferably provided as a continuous layer shared by the light-emitting devices. The hole-transport layers in the first EL layers 120, which are separated between the light-emitting devices of different emission colors, preferably have the same structure.

A conductive film having a property of transmitting visible light is used for either the pixel electrodes 101 or the common electrode 102, and a conductive film having a reflective property is used for the other. When the pixel electrodes 101 have light-transmitting properties and the common electrode 102 has a reflective property, a bottom-emission display apparatus can be provided, whereas when the pixel electrodes have reflective properties and the common electrode 102 has a light-transmitting property, a top-emission display apparatus can be provided. Note that when both the pixel electrodes and the common electrode 102 have light-transmitting properties, a dual-emission display apparatus can be obtained. The light-emitting device of one embodiment of the present invention is suitable as a top-emission light-emitting device.

The first EL layer 120R, the first EL layer 120G, and the first EL layer 120B are provided to cover end portions of the pixel electrode 101R, the pixel electrode 101G, and the pixel electrode 101B, respectively. The insulating layer 125 is provided to cover end portions of the first EL layer 120R, the first EL layer 120G, and the first EL layer 120B. In other words, the insulating layer 125 has opening portions overlapping with the pixel electrode 101R, the pixel electrode 101G, the pixel electrode 101B, the first EL layer 120R, the first EL layer 120G, and the first EL layer 120B. End portions of the insulating layer 125 in the opening portions are preferably tapered. Note that the end portions of the pixel electrode 101R, the pixel electrode 101G, and the pixel electrode 101B are not necessarily covered with the first EL layer 120R, the first EL layer 120G, and the first EL layer 120B, respectively.

The first EL layer 120R, the first EL layer 120G, and the first EL layer 120B include a region in contact with the top surfaces of the pixel electrode 101R, the pixel electrode 101G, and the pixel electrode 101B, respectively. The end portions of the first EL layer 120R, the first EL layer 120G, and the first EL layer 120B are positioned under the insulating layer 125. Each of the top surfaces of the first EL layer 120R, the first EL layer 120G, and the first EL layer 120B includes a region in contact with the insulating layer 125 and a region in contact with the second EL layer 121 (the common electrode 102 in the case where the second EL layer is not provided).

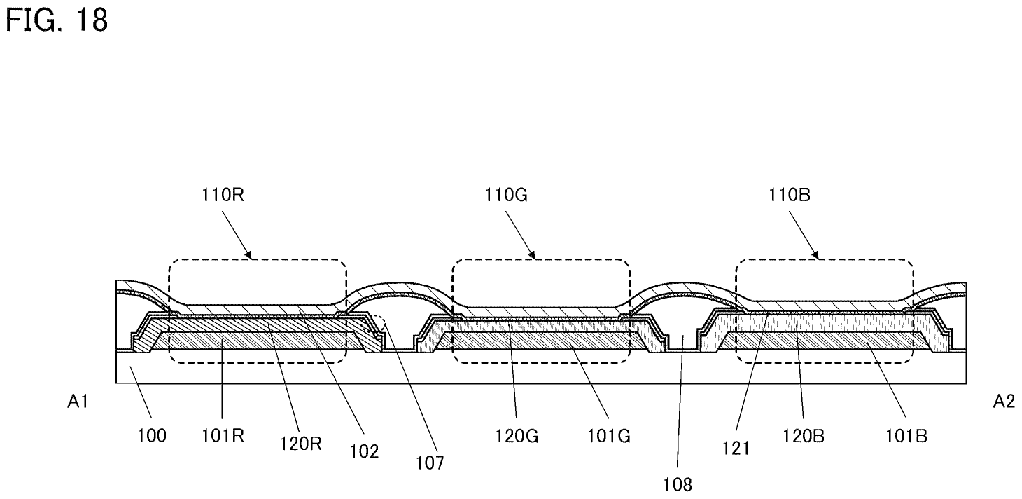

FIG. 18 is a modification example of FIG. 7B. In FIG. 18, the end portions of the pixel electrode 101R, the pixel electrode 101G, and the pixel electrode 101B have a tapered shape that extends toward the substrate, resulting in improvement in the coverage with a film formed thereover. In addition, the end portions of the pixel electrode 101R, the pixel electrode 101G, and the pixel electrode 101B are covered with the first EL layer 120R, the first EL layer 120G, and the first EL layer 120B, respectively. A mask layer 107 is formed to cover the EL layers. This inhibits the EL layers from being damaged at the time of etching by a photolithography method. An insulating layer 108 is provided between the light-emitting device 110R and the light-emitting device 110G, and between the light-emitting device 110G and the light-emitting device 110B. End portions of the insulating layers 108 have a gentle tapered shape, thereby suppressing disconnection of the second EL layer 121 and the common electrode 102 which are formed later.

As illustrated in FIG. 7B and FIG. 18, there is a gap between two EL layers of light-emitting devices of different colors. In this manner, the first EL layer 120R, the first EL layer 120G, and the first EL layer 120B are preferably provided so as not to be in contact with each other. This effectively prevents unintentional light emission from being caused by current flowing through two adjacent EL layers. As a result, the contrast can be increased to achieve a display apparatus with high display quality. The distance between facing end portions of EL layers of adjacent light-emitting devices (e.g., the light-emitting device 110R and the light-emitting device 110G) can be set greater than or equal to 2 m and less than or equal to 5 m by fabricating the light-emitting devices by a photolithography method. Note that the distance can be rephrased as the distance between the light-emitting layers included in the EL layers. It is difficult to set the distance less than 10 m by a formation method using a metal mask.

As described above, fabrication of the light-emitting apparatus by a photolithography method can greatly reduce the area of a non-light-emitting region that can exist between two light-emitting devices, thereby significantly increasing the aperture ratio. For example, in the display apparatus of one embodiment of the present invention, the aperture ratio higher than or equal to 40%, higher than or equal to 50%, higher than or equal to 60%, higher than or equal to 70%, higher than or equal to 80%, or higher than or equal to 90% and lower than 100% can be achieved.

Note that increasing the aperture ratio of the display apparatus can improve the reliability of the display apparatus. Specifically, with reference to the lifetime of a display apparatus including an organic EL device and having an aperture ratio of 10%, a display apparatus having an aperture ratio of 20% (that is, two times the aperture ratio of the reference) has a lifetime approximately 3.25 times as long as that of the reference, and a display apparatus having an aperture ratio of 40% (that is, four times the aperture ratio of the reference) has a lifetime approximately 10.6 times as long as that of the reference. Thus, the density of current flowing to the organic EL device can be reduced with increasing aperture ratio, and accordingly the lifetime of the display apparatus can be increased. The display apparatus of one embodiment of the present invention can have a higher aperture ratio and thus can have higher display quality. Furthermore, an excellent effect that the reliability (especially the lifetime) of the display apparatus is significantly improved with increasing aperture ratio of the display apparatus can be produced.

FIG. 7C illustrates an example in which the EL layer 120R is divided for the light-emitting devices in the Y direction. Note that FIG. 7C illustrates the cross sections of the light-emitting devices 110R as an example; the light-emitting device 110G and the light-emitting device 110B can have a similar shape. Note that the EL layer may be continuous in the Y direction and the EL layer 120R may be formed in a belt-like shape. When the EL layer 120R and the like are formed in a belt-like shape, no space for dividing the layer is needed and thus the area of a non-light-emitting region between the light-emitting devices can be reduced, resulting in a higher aperture ratio.

A protective layer 131 is provided over the common electrode 102 to cover the light-emitting device 110R, the light-emitting device 110G, and the light-emitting device 110B. The protective layer 131 has a function of preventing diffusion of impurities such as water into the light-emitting devices from above.

The protective layer 131 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 131.

As the protective layer 131, a stacked-layer film of an inorganic insulating film and an organic insulating film can be used. For example, a structure in which an organic insulating film is interposed between a pair of inorganic insulating films is preferable. Furthermore, the organic insulating film preferably functions as a planarization film. Thus, the top surface of the organic insulating film can be flat, and accordingly, coverage with the inorganic insulating film thereover can be improved, resulting in an improvement in barrier properties. Moreover, the protective layer 131 has a flat top surface, which is preferable because the influence of an uneven shape due to the lower structure can be reduced in the case where a component (e.g., a color filter, an electrode of a touch sensor, a lens array, or the like) is provided over the protective layer 131.

FIG. 7A also illustrates a connection electrode 101C that is electrically connected to the common electrode 102. The connection electrode 101C is supplied with a potential (e.g., an anode potential or a cathode potential) that is to be supplied to the common electrode 102. The connection electrode 101C is provided outside a display region where the light-emitting devices 110R and the like are arranged. In FIG. 7A, the common electrode 102 is denoted by a dashed line.

The connection electrode 101C can be provided along the outer periphery of the display region. For example, the connection electrode 101C may be provided along one side of the outer periphery of the display region or two or more sides of the outer periphery of the display region. That is, in the case where the display region has a rectangular top surface shape, the top surface shape of the connection electrode 101C can be a belt-like shape, an L shape, a U shape (a square bracket shape), a quadrangular shape, or the like.

FIG. 7D is a schematic cross-sectional view taken along the dashed-dotted line C1-C2 in FIG. 7A. FIG. 7D illustrates a connection portion 130 in which the connection electrode 101C is electrically connected to the common electrode 102. In the connection portion 130, the common electrode 102 is provided over and in contact with the connection electrode 101C and the protective layer 131 is provided to cover the common electrode 102. In addition, an insulating layer 124 is provided to cover end portions of the connection electrode 101C.

### Fabrication Method Example 1

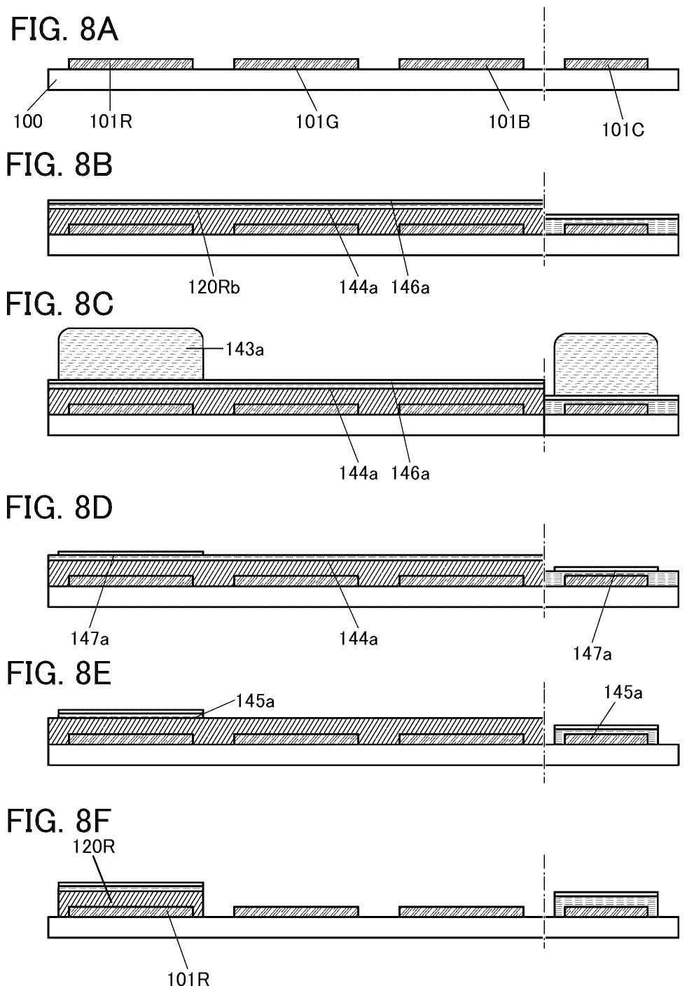

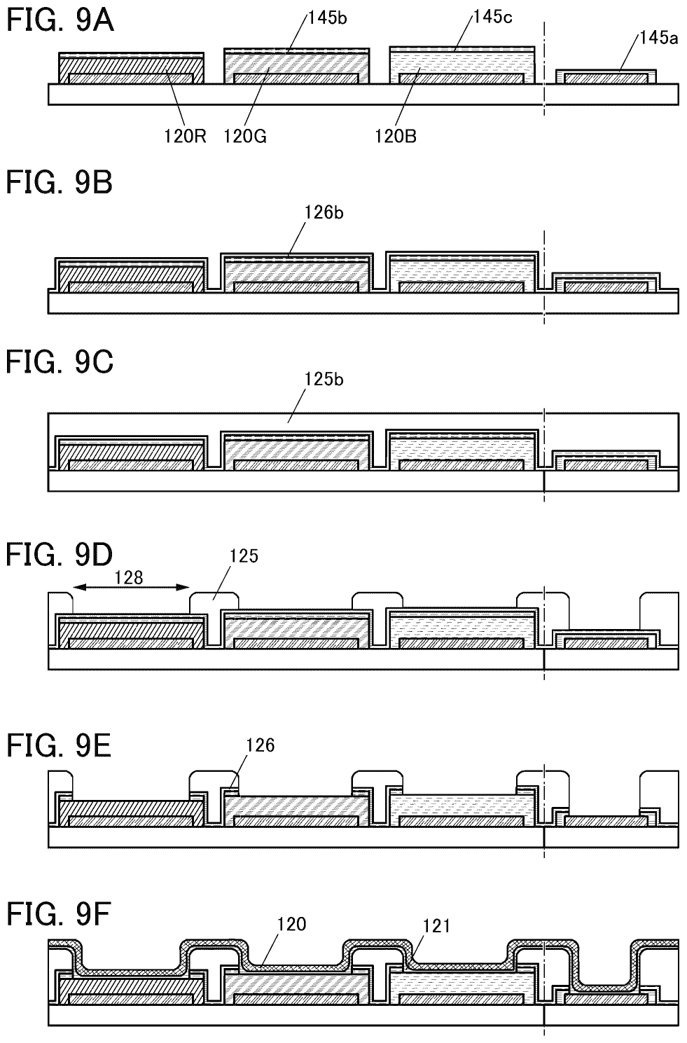

An example of a method for fabricating the display apparatus of one embodiment of the present invention will be described below with reference to drawings. Here, description is made with use of the light-emitting apparatus 450 described in the above structure example. FIG. 8A to FIG. 9F are each a schematic cross-sectional view of a step in a method for fabricating the display apparatus described below. In FIG. 8A and the like, the schematic cross-sectional views of the connection portion 130 and the periphery thereof are also illustrated on the right side.

Note that thin films included in the display apparatus (insulating films, semiconductor films, conductive films, and the like) can be formed by any of a sputtering method, a chemical vapor deposition (CVD) method, a vacuum evaporation method, a pulsed laser deposition (PLD) method, an atomic layer deposition (ALD) method, and the like. Examples of the CVD method include a plasma-enhanced chemical vapor deposition (PECVD) method and a thermal CVD method. An example of a thermal CVD method is a metal organic chemical vapor deposition (MOCVD) method.

Alternatively, thin films included in the display apparatus (insulating films, semiconductor films, conductive films, and the like) can be formed by a method such as spin coating, dipping, spray coating, ink-jetting, dispensing, screen printing, offset printing, a doctor knife method, a slit coater, a roll coater, a curtain coater, or a knife coater.

Thin films included in the display apparatus can be processed by a photolithography method or the like. Besides, a nanoimprinting method, a sandblasting method, a lift-off method, or the like may be used to process thin films. Alternatively, island-shaped thin films may be directly formed by a deposition method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then the thin film is processed into a desired shape by performing light exposure and development.

As light used for light exposure in a photolithography method, light with an i-line (with a wavelength of 365 nm), light with a g-line (with a wavelength of 436 nm), light with an h-line (with a wavelength of 405 nm), or light in which the i-line, the g-line, and the h-line are mixed can be used. Alternatively, ultraviolet light, KrF laser light, ArF laser light, or the like can be used. Light exposure may be performed by liquid immersion exposure technique. As the light used for light exposure, extreme ultraviolet (EUV) light or X-rays may also be used. Furthermore, instead of the light used for the light exposure, an electron beam can also be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblasting method, or the like can be used.

In this specification and the like, a device formed using a metal mask or an FMM (fine metal mask, high-resolution metal mask) may be referred to as a device having an MM (metal mask) structure. In addition, in this specification and the like, a device formed without using a metal mask or an FMM may be referred to as a device having an MML (metal maskless) structure.

### [Preparation for Substrate 100]

A substrate that has heat resistance high enough to withstand at least heat treatment performed later can be used as a substrate 100. When an insulating substrate is used as the substrate 100, a glass substrate, a quartz substrate, a sapphire substrate, a ceramic substrate, an organic resin substrate, or the like can be used. Alternatively, a semiconductor substrate such as a single crystal semiconductor substrate or a polycrystalline semiconductor substrate of silicon, silicon carbide, or the like; a compound semiconductor substrate of silicon germanium or the like; or an SOI substrate can be used.

As the substrate 100, it is particularly preferable to use the semiconductor substrate or the insulating substrate where a semiconductor circuit including a semiconductor element such as a transistor is formed. The semiconductor circuit preferably forms a pixel circuit, a gate line driver circuit (a gate driver), a source line driver circuit (a source driver), or the like. In addition to the above, an arithmetic circuit, a memory circuit, or the like may be formed.

### [Formation of Pixel Electrodes 101R, 101G, and 101B and Connection Electrode 101C]

Next, the pixel electrode 101R, the pixel electrode 101G, the pixel electrode 101B, and the connection electrode 101C are formed over the substrate 100. First, a conductive film to be the pixel electrodes (anodes) is formed, a resist mask is formed by a photolithography method, and an unnecessary portion of the conductive film is removed by etching. After that, the resist mask is removed to form the pixel electrode 101R, the pixel electrode 101G, and the pixel electrode 101B.

In the case where a conductive film with a property of reflecting visible light is used as each pixel electrode, it is preferable to use a material (e.g., silver or aluminum) having reflectance as high as possible in the whole wavelength range of visible light. This can increase color reproducibility as well as light extraction efficiency of the light-emitting devices. In the case where a conductive film with a property of reflecting visible light is used as each pixel electrode, what is called a top-emission light-emitting apparatus in which light is extracted in the direction opposite to the substrate can be obtained. In the case where a conductive film with a light-transmitting property is used as each pixel electrode, what is called a bottom-emission light-emitting apparatus in which light is extracted in the direction of the substrate can be obtained.

### [Formation of EL Film 120Rb]

Subsequently, an EL film 120Rb to be the EL layer 120R later is formed over the pixel electrode 101R, the pixel electrode 101G, and the pixel electrode 101B.

The EL film 120Rb includes at least a light-emitting layer containing a light-emitting material and a hole-transport layer. It is also possible to employ a structure in which one or more films functioning as an electron-injection layer, an electron-transport layer, a charge-generation layer, and a hole-injection layer are stacked in addition to the above. The EL film 120Rb can be formed by, for example, an evaporation method, a sputtering method, an ink-jet method, or the like. Note that without limitation to this, the above deposition method can be used as appropriate.

For example, the EL film 120Rb is preferably a stacked-layer film in which a hole-injection layer, a hole-transport layer, a light-emitting layer, and an electron-transport layer are stacked in this order. In that case, a film including an electron-injection layer can be used as the EL layer 121 formed later.

The EL film 120Rb is preferably formed so as not to be provided over the connection electrode 101C. For example, in the case where the EL film 120Rb is formed by an evaporation method (or a sputtering method), it is preferable that the EL film 120Rb be formed using a shielding mask or be removed in a later etching step so as not to be formed over the connection electrode 101C.

[Formation of Mask Film 144a]

Next, a mask film 144a is formed to cover the EL film 120Rb. The mask film 144a is provided in contact with the top surface of the connection electrode 101C.

As the mask film 144a, it is possible to use a film highly resistant to etching treatment performed on EL films such as the EL film 120Rb, i.e., a film having high etching selectivity. Furthermore, as the mask film 144a, it is possible to use a film having high etching selectivity with respect to a protective film such as a protective film 146a described later. Moreover, as the mask film 144a, it is possible to use a film that can be removed by a wet etching method causing less damage to the EL films.

As the mask film 144a, an inorganic film such as a metal film, an alloy film, a metal oxide film, a semiconductor film, or an inorganic insulating film can be used, for example. The mask film 144a can be formed by any of a variety of deposition methods such as a sputtering method, an evaporation method, a CVD method, and an ALD method.

For the mask film 144a, for example, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

For the mask film 144a, a metal oxide such as indium gallium zinc oxide (In—Ga—Zn oxide, also referred to as IGZO) can be used. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon, or the like can also be used.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium described above. In particular, M is preferably one or more kinds selected from gallium, aluminum, and yttrium.

For the mask film 144a, an inorganic insulating material such as aluminum oxide, hafnium oxide, or silicon oxide can also be used. In particular, aluminum oxide is preferable.

For the mask film 144a, a material that can be dissolved in a solvent chemically stable with respect to at least the uppermost film of the EL film 120Rb is preferably used. Specifically, a material that will be dissolved in water or alcohol can be suitably used for the mask film 144a. In formation of the mask film 144a, it is preferable that application of such a material dissolved in a solvent such as water or alcohol be performed by a wet deposition method and followed by heat treatment for evaporating the solvent. At this time, the heat treatment is preferably performed in a reduced-pressure atmosphere, in which case the solvent can be removed at a low temperature in a short time and thermal damage to the EL film 120Rb can be reduced accordingly.

As a wet deposition method for forming the mask film 144a, spin coating, dipping, spray coating, ink-jetting, dispensing, screen printing, offset printing, a doctor knife method, a slit coater, a roll coater, a curtain coater, a knife coater, or the like can be given.

For the mask film 144a, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin can be used.

Here, a film formed especially by an ALD method is dense and has high capability of protecting the EL layers, and thus can be suitably used as a mask film. In particular, an aluminum oxide film is preferable.

[Formation of Protective Film 146a]

Next, the protective film 146a is formed over the mask film 144a (FIG. 8B).

The protective film 146a is a film used as a hard mask when the mask film 144a is etched later. In a later step of processing the protective film 146a, the mask film 144a is exposed. Thus, the combination of films having high etching selectivity therebetween is selected for the mask film 144a and the protective film 146a. It is thus possible to select a film that can be used for the protective film 146a depending on an etching condition of the mask film 144a and an etching condition of the protective film 146a.

For example, in the case where dry etching using a gas containing fluorine (also referred to as a fluorine-based gas) is performed for the etching of the protective film 146a, the protective film 146a can be formed using silicon, silicon nitride, silicon oxide, tungsten, titanium, molybdenum, tantalum, tantalum nitride, an alloy containing molybdenum and niobium, an alloy containing molybdenum and tungsten, or the like. Here, a metal oxide film using IGZO, ITO, or the like is given as a film having high etching selectivity (that is, enabling low etching rate) in dry etching using the fluorine-based gas, and such a film can be used as the mask film 144a.

Note that without being limited to the above, a material of the protective film 146a can be selected from a variety of materials depending on the etching condition of the mask film 144a and the etching condition of the protective film 146a. For example, any of the films that can be used for the mask film 144a can be selected.

As the protective film 146a, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

As the protective film 146a, an oxide film can also be used. Typically, it is possible to use an oxide film or an oxynitride film such as silicon oxide, silicon oxynitride, aluminum oxide, aluminum oxynitride, hafnium oxide, or hafnium oxynitride.

Alternatively, as the protective film 146a, an organic film that can be used for the EL film 120Rb or the like can be used. For example, the organic film that is used as the EL film 120Rb, an EL film 120Gb, or an EL film 120Bb can be used as the protective film 146a. The use of such an organic film is preferable, in which case the deposition apparatus for the EL film 120Rb or the like can be used in common.

[Formation of Resist Mask 143a]

Then, a resist mask 143a is formed in a position being over the protective film 146a and overlapping with the pixel electrode 101R and a position being over the protective film 146a and overlapping with the connection electrode 101C (FIG. 8C).

For the resist mask 143a, a resist material containing a photosensitive resin such as a positive type resist material or a negative type resist material can be used.

In the case where the resist mask 143a is formed over the mask film 144a without the protective film 146a therebetween, there is a risk of dissolving the EL film 120Rb due to a solvent of the resist material if a defect such as a pinhole exists in the mask film 144a. Such a defect can be prevented by using the protective film 146a.

In the case where a film that is unlikely to cause a defect such as a pinhole is used as the mask film 144a, the resist mask 143a may be formed directly on the mask film 144a without the protective film 146a therebetween.

[Etching of Protective Film 146a]

Next, part of the protective film 146a that is not covered with the resist mask 143a is removed by etching, so that a belt-shaped protective layer 147a is formed. At that time, the protective layer 147a is formed also over the connection electrode 101C.

In the etching of the protective film 146a, an etching condition with high selectivity is preferably employed so that the mask film 144a is not removed by the etching. Either wet etching or dry etching can be performed as the etching of the protective film 146a; a reduction in a pattern of the protective film 146a can be inhibited with use of dry etching.

[Removal of Resist Mask 143a]

Next, the resist mask 143a is removed (FIG. 8D).

The removal of the resist mask 143a can be performed by wet etching or dry etching. It is particularly preferable to perform dry etching (also referred to as plasma ashing) using an oxygen gas as an etching gas to remove the resist mask 143a.

At this time, the removal of the resist mask 143a is performed in a state where the EL film 120Rb is covered with the mask film 144a; thus, the EL film 120Rb is less likely to be affected by the removal. This is particularly suitable in the case where etching using an oxygen gas, such as plasma ashing, is performed because the electrical characteristics might be adversely affected when the EL film 120Rb is exposed to oxygen.

[Etching of Mask Film 144a]

Next, part of the mask film 144a that is not covered with the protective layer 147a is removed by etching with use of the protective layer 147a as a mask, so that a belt-shaped mask layer 145a is formed (FIG. 8E). At that time, the mask layer 145a is formed also over the connection electrode 101C.

Either wet etching or dry etching can be performed for the etching of the mask film 144a; the use of a dry etching method is preferable, in which case shrinkage of the pattern can be inhibited.

[Etching of EL Film 120Rb and Protective Layer 147a]

Next, part of the EL film 120Rb that is not covered with the mask layer 145a is removed by etching at the same time as etching of the protective layer 147a, whereby the belt-shaped EL layer 120R is formed (FIG. 8F). At that time, the protective layer 147a over the connection electrode 101C is also removed.

The EL film 120Rb and the protective layer 147a are preferably etched by the same treatment so that the process can be simplified to reduce the fabrication cost of the display apparatus.

For the etching of the EL film 120Rb, it is particularly preferable to perform dry etching using an etching gas that does not contain oxygen as its main component. This can inhibit a change in the quality of the EL film 120Rb to achieve a highly reliable display apparatus. Examples of the etching gas that does not contain oxygen as its main component include CF₄, C₄F₈, SF₆, CHF₃, Cl₂, H₂O, BCl₃, H₂, and a noble gas such as He. Alternatively, a mixed gas of the above gas and a dilution gas that does not contain oxygen can be used as the etching gas.

Note that the etching of the EL film 120Rb and the etching of the protective layer 147a may be performed separately. In that case, either the etching of the EL film 120Rb or the etching of the protective layer 147a may be performed first.

At this step, the EL layer 120R and the connection electrode 101C are covered with the mask layer 145a.

### [Formation of EL Layer 120G and EL Layer 120B]

By repeating similar steps, the island-shaped EL layers 120G and 120B and island-shaped mask layers 145b and 145c can be formed (FIG. 9A).

### [Removal of Mask Layer]

Next, an insulating layer 126b is formed over the mask layer 145a, the mask layer 145b, and the mask layer 145c. The insulating layer 126b can be formed in a manner similar to that of the mask layer 145a, the mask layer 145b, and the mask layer 145c.

[Formation of Insulating Layer 125b]

Then, an insulating layer 125b is formed to cover the insulating layer 126b. The insulating layer 125b is formed using a photosensitive organic resin. As the organic material, for example, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used. Alternatively, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin can be used for the insulating layer 125b in some cases. As the photosensitive resin, a photoresist can be used in some cases. As the photosensitive resin, a positive photosensitive material or a negative photosensitive material can be used in some cases.

The insulating layer 125b is preferably subjected to heat treatment after application. The heat treatment is performed at a temperature lower than the upper temperature limit of the EL layers. The substrate temperature at the time of the heat treatment is higher than or equal to 50° C. and lower than or equal to 200° C., preferably higher than or equal to 60° C. and lower than or equal to 150° C., further preferably higher than or equal to 70° C. and lower than or equal to 120° C. Accordingly, a solvent contained in the insulating layer 125b can be removed.

Next, as illustrated in FIG. 7C, the opening portions 128 are formed in regions of the insulating layer 125b that overlap with the pixel electrodes and the first EL layers by performing light exposure and development, and the insulating layer 125 is formed. In the case where a positive acrylic resin is used for the insulating layer 125b, a region where the insulating layer 125b is removed is irradiated with visible light or ultraviolet rays using a mask.

In the case where visible light is used for light exposure, the visible light preferably includes the i-line (with a wavelength of 365 nm). Furthermore, visible light including the g-line (with a wavelength of 436 nm), the h-line (with a wavelength of 405 nm), or the like may be used.

In the case where an acrylic resin is used for the insulating layer 125b, an alkaline solution is preferably used as a developer in development, and for example, an aqueous solution of tetramethyl ammonium hydroxide (TMAH) is used.

Then, light exposure is preferably performed on the entire substrate so that the insulating layer 125 is irradiated with visible light or ultraviolet rays. The energy density for the light exposure is higher than 0 mJ/cm² and lower than or equal to 800 mJ/cm², preferably higher than 0 mJ/cm² and lower than or equal to 500 mJ/cm². Performing such light exposure after development can improve the transparency of the insulating layer 125 in some cases. In addition, it is sometimes possible to lower the substrate temperature required for subsequent heat treatment for changing the end portions of the insulating layer 125 into a tapered shape.

Next, the heat treatment is performed so that the insulating layer 125b can be changed into the insulating layer 125 having a taper-shaped side surface. The heat treatment is performed at a temperature lower than the upper temperature limit of the EL layers. The substrate temperature at the time of the heat treatment is higher than or equal to 50° C. and lower than or equal to 200° C., preferably higher than or equal to 60° C. and lower than or equal to 150° C., further preferably higher than or equal to 70° C. and lower than or equal to 130° C. The substrate temperature in the heat treatment of this step is preferably higher than that in the heat treatment after the application of the insulating layer 125. Accordingly, corrosion resistance of the insulating layer 125 can also be improved.

Next, the exposed mask layer 145a, mask layer 145b, and mask layer 145c are removed. The mask layer 145a, the mask layer 145b, and the mask layer 145c can be removed by wet etching or dry etching. At this time, a method that causes damage to the EL layer 120R, the EL layer 120G, and the EL layer 120B as little as possible is preferably employed. In particular, a wet etching method is preferably used. For example, wet etching using an aqueous solution of tetramethyl ammonium hydroxide (TMAH), diluted hydrofluoric acid, oxalic acid, phosphoric acid, acetic acid, nitric acid, or a mixed solution thereof is preferably performed.

Alternatively, the mask layer 145a, the mask layer 145b, and the mask layer 145c are preferably removed by being dissolved in a solvent such as water or alcohol. Examples of the alcohol in which the mask layer 145a, the mask layer 145b, and the mask layer 145c can be dissolved include ethyl alcohol, methyl alcohol, isopropyl alcohol (IPA), and glycerin.

After the mask layer 145a, the mask layer 145b, and the mask layer 145c are removed, drying treatment is preferably performed in order to remove water contained in the EL layer 120R, the EL layer 120G, and the EL layer 120B and water adsorbed on the surfaces of the EL layer 120R, the EL layer 120G, and the EL layer 120B. For example, heat treatment is preferably performed in an inert gas atmosphere or a reduced-pressure atmosphere. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

In the above manner, the EL layer 120R, the EL layer 120G, and the EL layer 120B can be separately formed.

### [Formation of EL Layer 121]

Then, the EL layer 121 is formed to cover the EL layer 120R, the EL layer 120G, the EL layer 120B, and the insulating layer 125.

The EL layer 121 can be formed in a manner similar to that for the EL film 120Rb or the like. In the case where the EL layer 121 is formed by an evaporation method, the EL layer 121 is preferably formed using a shielding mask so as not to be formed over the connection electrode 101C.

### [Formation of Common Electrode 102]

Then, the common electrode 102 is formed to cover the EL layer 121 and the connection electrode 101C (FIG. 9F).

The common electrode 102 can be formed by a deposition method such as an evaporation method or a sputtering method. Alternatively, a film formed by an evaporation method and a film formed by a sputtering method may be stacked. In that case, the common electrode 102 is preferably formed so as to cover a region where the electron-injection layer 115 is formed. That is, a structure in which an end portion of the electron-injection layer 115 overlaps with the common electrode 102 can be obtained. The common electrode 102 is preferably formed using a shielding mask.

The common electrode 102 is electrically connected to the connection electrode 101C outside a display region.

### [Formation of Protective Layer]

Then, a protective layer is formed over the common electrode 102. An inorganic insulating film used for the protective layer is preferably formed by a sputtering method, a PECVD method, or an ALD method. In particular, an ALD method is preferable because it provides excellent step coverage and is less likely to cause a defect such as a pinhole. An organic insulating film is preferably formed by an ink-jet method because a uniform film can be formed in a desired area.

Through the above steps, the light-emitting apparatus of one embodiment of the present invention can be fabricated.

Although the case where the common electrode 102 and the second EL layer 121 are formed to have different top surface shapes is described above, they may be formed in the same region.

### Embodiment 5

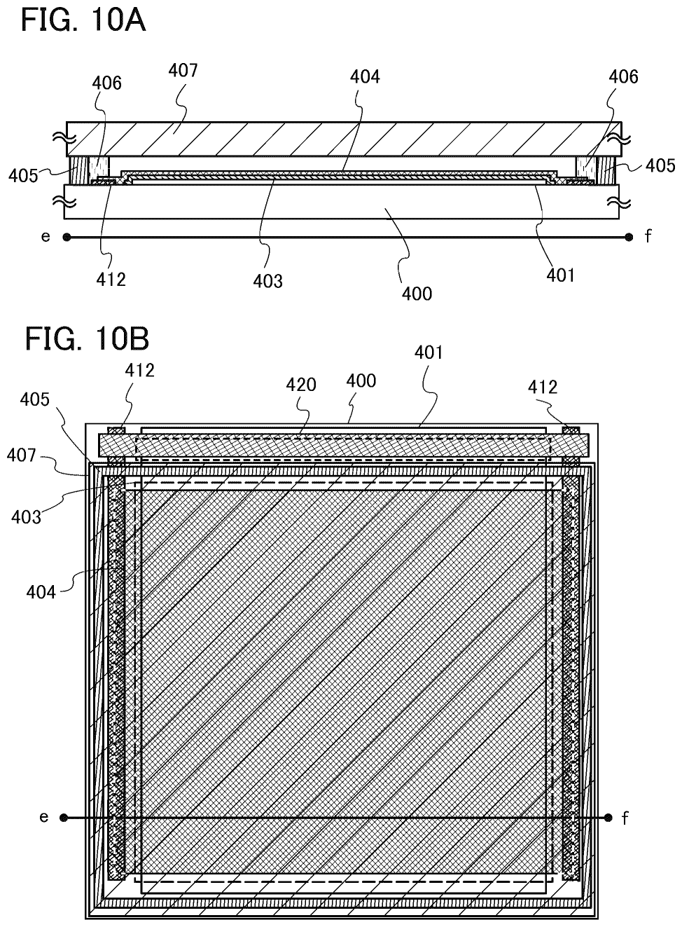

In this embodiment, an example in which the light-emitting device described in Embodiment 1 and Embodiment 2 is used for a lighting device will be described with reference to FIG. 10. FIG. 10B is a top view of the lighting device, and FIG. 10A is a cross-sectional view taken along the line e-f in FIG. 10B.

In the lighting device in this embodiment, an anode 401 is formed over a substrate 400 which is a support with a light-transmitting property. The anode 401 corresponds to the pixel electrode 101 in Embodiment 1. When light is extracted through the anode 401, the anode 401 is formed using a material having a light-transmitting property.

A pad 412 for supplying voltage to a cathode 404 is formed over the substrate 400.

An EL layer 403 is formed over the anode 401. The structure of the EL layer 403 corresponds to, for example, the structure of the EL layer 103 in Embodiment 1 and Embodiment 2. Refer to the corresponding description for the structure.

The cathode 404 is formed to cover the EL layer 403. The cathode 404 corresponds to the common electrode 102 in Embodiment 1. The cathode 404 is formed using a material having high reflectance when light is extracted through the anode 401. The cathode 404 is connected to the pad 412, thereby receiving voltage.

As described above, the lighting device described in this embodiment includes a light-emitting device including the anode 401, the EL layer 403, and the cathode 404. Since the light-emitting device is a light-emitting device with high emission efficiency, the lighting device in this embodiment can have low power consumption.

The substrate 400 provided with the light-emitting device having the above structure is fixed to a sealing substrate 407 with sealing materials 405 and 406 and sealing is performed, whereby the lighting device is completed. It is possible to use only either the sealing material 405 or the sealing material 406. The inner sealing material 406 (not illustrated in FIG. 10B) can be mixed with a desiccant which enables moisture to be adsorbed, increasing reliability.

When parts of the pad 412 and the anode 401 are extended to the outside of the sealing materials 405 and 406, the extended parts can serve as external input terminals. An IC chip 420 mounted with a converter or the like may be provided over the external input terminals, for example.

The lighting device described in this embodiment includes, as an EL element, the light-emitting device described in Embodiment 1 and Embodiment 2 and thus has high emission efficiency; hence, the light-emitting apparatus can have low power consumption.

This embodiment can be freely combined with any of the other embodiments.

### Embodiment 6

In this embodiment, examples of electronic appliances each including the light-emitting device described in Embodiment 1 and Embodiment 2 will be described. The light-emitting device described in Embodiment 1 and Embodiment 2 is a light-emitting device having high emission efficiency (especially, BI). As a result, the electronic appliances described in this embodiment each of which includes the light-emitting device having high emission efficiency can have low power consumption.

Examples of the electronic appliance including the above light-emitting device include television devices (also referred to as TV or television receivers), monitors for computers and the like, digital cameras, digital video cameras, digital photo frames, cellular phones (also referred to as mobile phones or mobile phone devices), portable game machines, portable information terminals, audio playback devices, and large game machines such as pachinko machines. Specific examples of these electronic appliances are described below.

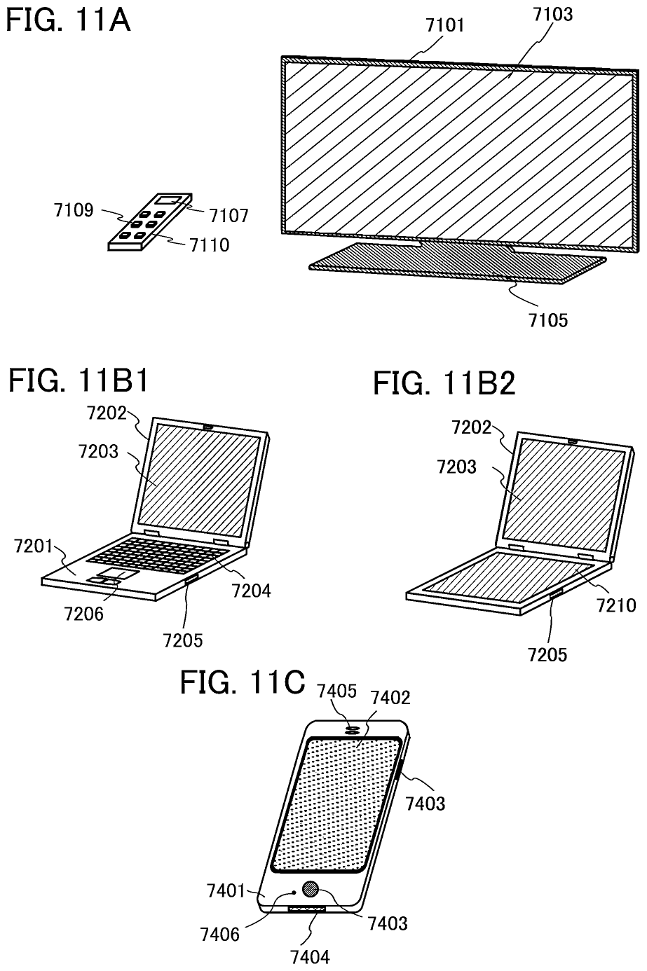

FIG. 11A illustrates an example of a television device. In the television device, a display portion 7103 is incorporated in a housing 7101. Here, the housing 7101 is supported by a stand 7105. Videos can be displayed on the display portion 7103, and in the display portion 7103, the light-emitting devices described in Embodiment 1 and Embodiment 2 are arranged in a matrix.

The television device can be operated with an operation switch of the housing 7101 or a separate remote controller 7110. With operation keys 7109 of the remote controller 7110, channels and volume can be controlled and videos displayed on the display portion 7103 can be controlled. Furthermore, the remote controller 7110 may be provided with a display portion 7107 for displaying information output from the remote controller 7110. The light-emitting devices described in Embodiment 1 and Embodiment 2 may also be arranged in a matrix in the display portion 7107.

Note that the television device is provided with a receiver, a modem, and the like. With the use of the receiver, a general television broadcast can be received. Moreover, when the television device is connected to a communication network with or without wires via the modem, one-way (from a sender to a receiver) or two-way (between a sender and a receiver or between receivers) information communication can be performed.

FIG. 11B1 illustrates a computer, which includes a main body 7201, a housing 7202, a display portion 7203, a keyboard 7204, an external connection port 7205, a pointing device 7206, and the like. Note that this computer is fabricated using the light-emitting devices described in Embodiment 1 and Embodiment 2 and arranged in a matrix in the display portion 7203. The computer illustrated in FIG. 11B1 may have a structure illustrated in FIG. 11B2. A computer illustrated in FIG. 11B2 is provided with a display portion 7210 instead of the keyboard 7204 and the pointing device 7206. The display portion 7210 is a touch panel, and input operation can be performed by touching display for input on the display portion 7210 with a finger or a dedicated pen. The display portion 7210 can also display images other than the display for input. The display portion 7203 may also be a touch panel. Connecting the two screens with a hinge can prevent troubles; for example, the screens can be prevented from being cracked or broken while the computer is being stored or carried.

FIG. 11C illustrates an example of a portable terminal. A cellular phone is provided with a display portion 7402 incorporated in a housing 7401, operation buttons 7403, an external connection port 7404, a speaker 7405, a microphone 7406, and the like. Note that the cellular phone has the display portion 7402 in which the light-emitting devices described in Embodiment 1 and Embodiment 2 are arranged in a matrix.

When the display portion 7402 of the portable terminal illustrated in FIG. 11C is touched with a finger or the like, information can be input. In this case, operations such as making a call and creating an e-mail can be performed by touching the display portion 7402 with a finger or the like.

The display portion 7402 has mainly three screen modes. The first mode is a display mode mainly for displaying images, and the second mode is an input mode mainly for inputting information such as text. The third mode is a display-and-input mode in which the two modes, the display mode and the input mode, are combined.

For example, in the case of making a call or creating an e-mail, a text input mode mainly for inputting text is selected for the display portion 7402 so that text displayed on the screen can be input. In this case, it is preferable to display a keyboard or number buttons on almost the entire screen of the display portion 7402.

When a sensing device including a sensor such as a gyroscope sensor or an acceleration sensor for detecting inclination is provided inside the portable terminal, display on the screen of the display portion 7402 can be automatically changed by determining the orientation of the portable terminal (whether the portable terminal is placed horizontally or vertically).

The screen modes are switched by touching the display portion 7402 or operating the operation buttons 7403 of the housing 7401. Alternatively, the screen modes can be switched depending on the kind of images displayed on the display portion 7402. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 7402 is not performed for a certain period while a signal sensed by an optical sensor in the display portion 7402 is sensed, the screen mode may be controlled so as to be switched from the input mode to the display mode.

The display portion 7402 may also function as an image sensor. For example, an image of a palm print, a fingerprint, or the like is taken when the display portion 7402 is touched with the palm or the finger, whereby personal authentication can be performed. Furthermore, by providing a backlight or a sensing light source that emits near-infrared light in the display portion, an image of a finger vein, a palm vein, or the like can be taken.

As described above, the application range of the light-emitting apparatus including the light-emitting device described in Embodiment 1 and Embodiment 2 is so wide that this light-emitting apparatus can be used in electronic appliances in a variety of fields. By using the light-emitting device described in Embodiment 1 and Embodiment 2, an electronic appliance with low power consumption can be obtained.

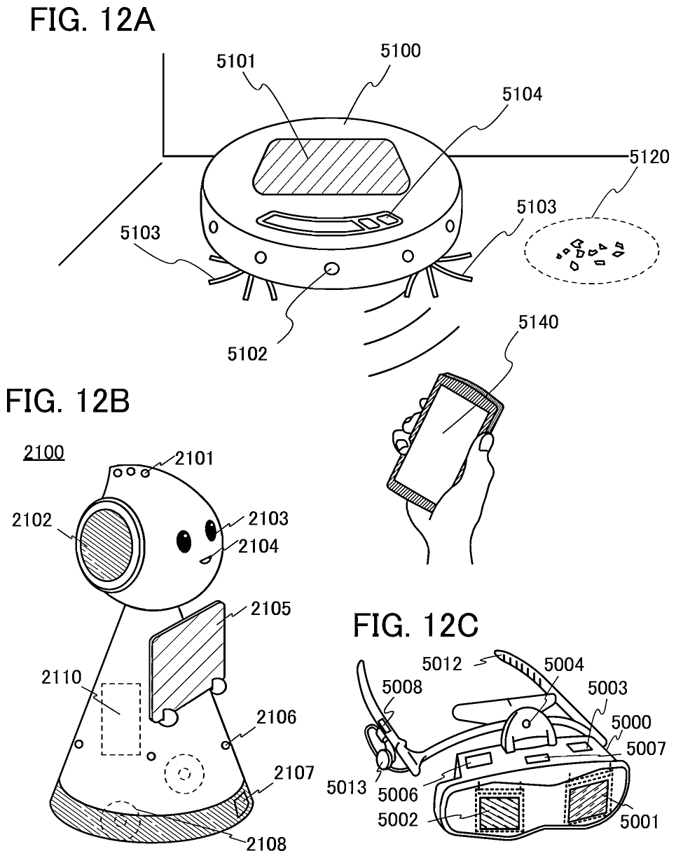

FIG. 12A is a schematic view illustrating an example of a cleaning robot.

A cleaning robot 5100 includes a display 5101 on its top surface, a plurality of cameras 5102 on its side surface, a brush 5103, and operation buttons 5104. Although not illustrated, the bottom surface of the cleaning robot 5100 is provided with a tire, an inlet, and the like. Furthermore, the cleaning robot 5100 includes various sensors such as an infrared sensor, an ultrasonic sensor, an acceleration sensor, a piezoelectric sensor, an optical sensor, and a gyroscope sensor. The cleaning robot 5100 has a wireless communication means.

The cleaning robot 5100 is self-propelled, detects dust 5120, and vacuums the dust through the inlet provided on the bottom surface.

The cleaning robot 5100 can determine whether there is an obstacle such as a wall, furniture, or a step by analyzing images taken by the cameras 5102. When an object that is likely to be caught in the brush 5103, such as a wire, is sensed by image analysis, the rotation of the brush 5103 can be stopped.

The display 5101 can display the remaining capacity of a battery, the amount of vacuumed dust, and the like. The display 5101 may display a path on which the cleaning robot 5100 has run. The display 5101 may be a touch panel, and the operation buttons 5104 may be provided on the display 5101.

The cleaning robot 5100 can communicate with a portable electronic appliance 5140 such as a smartphone. Images taken by the cameras 5102 can be displayed on the portable electronic appliance 5140. Accordingly, an owner of the cleaning robot 5100 can monitor his/her room even when the owner is not at home. The owner can also check the display on the display 5101 by the portable electronic appliance such as a smartphone.

The light-emitting apparatus of one embodiment of the present invention can be used for the display 5101.

A robot 2100 illustrated in FIG. 12B includes an arithmetic device 2110, an illuminance sensor 2101, a microphone 2102, an upper camera 2103, a speaker 2104, a display 2105, a lower camera 2106, an obstacle sensor 2107, and a moving mechanism 2108.

The microphone 2102 has a function of sensing a speaking voice of a user, an environmental sound, and the like. The speaker 2104 has a function of outputting sound. The robot 2100 can communicate with a user using the microphone 2102 and the speaker 2104.

The display 2105 has a function of displaying various kinds of information. The robot 2100 can display information desired by a user on the display 2105. The display 2105 may be provided with a touch panel. Moreover, the display 2105 may be a detachable information terminal, in which case charging and data communication can be performed when the display 2105 is set at the home position of the robot 2100.

The upper camera 2103 and the lower camera 2106 each have a function of taking an image of the surroundings of the robot 2100. The obstacle sensor 2107 can detect an obstacle in the direction where the robot 2100 advances with the moving mechanism 2108. The robot 2100 can move safely by recognizing the surroundings with the upper camera 2103, the lower camera 2106, and the obstacle sensor 2107. The light-emitting apparatus of one embodiment of the present invention can be used for the display 2105.

FIG. 12C illustrates an example of a goggle-type display. The goggle-type display includes, for example, a housing 5000, a display portion 5001, a speaker 5003, an LED lamp 5004 (including a power switch or an operation switch), a connection terminal 5006, a sensor 5007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared ray), a microphone 5008, a second display portion 5002, a support portion 5012, and an earphone 5013.

The light-emitting apparatus of one embodiment of the present invention can be used for the display portion 5001 and the second display portion 5002.

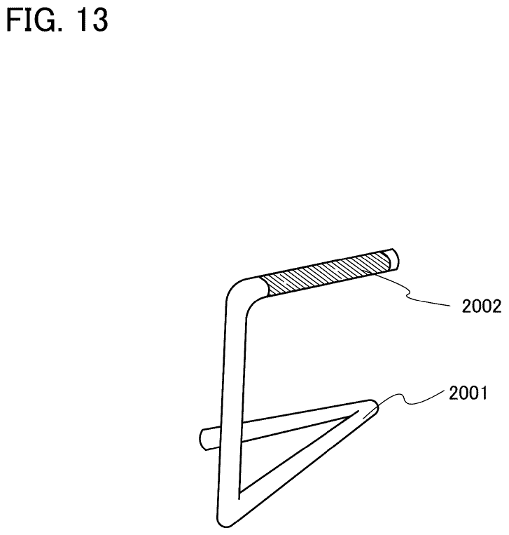

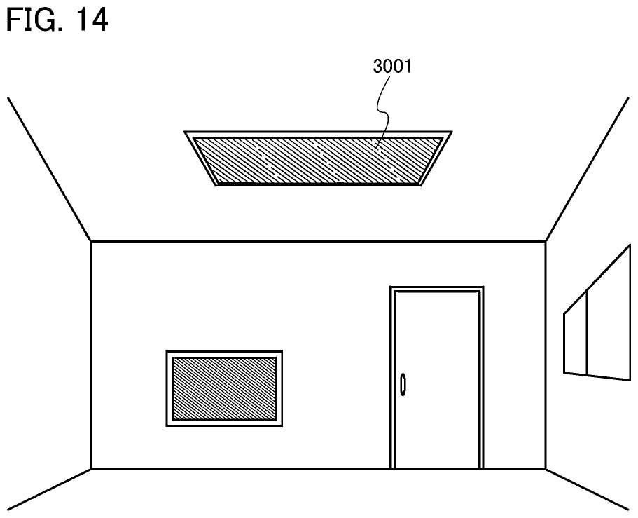

FIG. 13 illustrates an example in which the light-emitting device described in Embodiment 1 and Embodiment 2 is used for a table lamp which is a lighting device. The table lamp illustrated in FIG. 13 includes a housing 2001 and a light source 2002.

FIG. 14 illustrates an example in which the light-emitting device described in Embodiment 1 and Embodiment 2 is used for an indoor lighting device 3001. Since the light-emitting device described in Embodiment 1 and Embodiment 2 has high emission efficiency, the lighting device can have low power consumption. Furthermore, since the light-emitting device described in Embodiment 1 and Embodiment 2 is thin, the light-emitting device can be used for a lighting device having a reduced thickness.

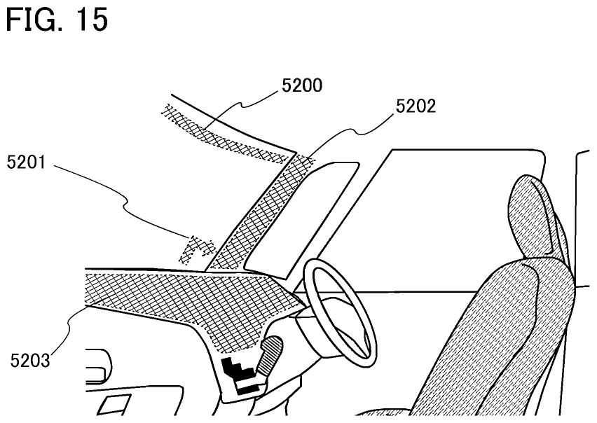

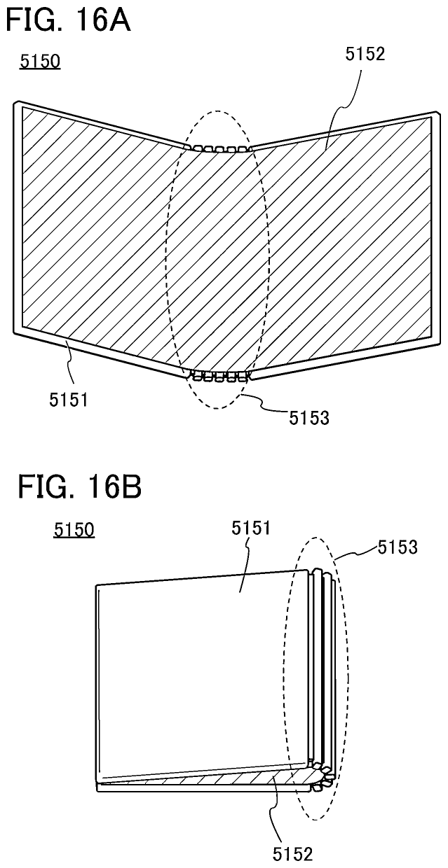

The light-emitting device described in Embodiment 1 and Embodiment 2 can also be used for an automobile windshield or an automobile dashboard. FIG. 15 illustrates a mode in which the light-emitting devices described in Embodiment 1 and Embodiment 2 are used for an automobile windshield or an automobile dashboard. A display region 5200 to a display region 5203 each include the light-emitting device described in Embodiment 1 and Embodiment 2.

The display region 5200 and the display region 5201 are display apparatuses which are provided in the automobile windshield and include the light-emitting devices described in Embodiment 1 and Embodiment 2. The light-emitting device described in Embodiment 1 and Embodiment 2 can be formed into what is called a see-through display apparatus, through which the opposite side can be seen, by including an anode and a cathode formed of light-transmitting electrodes. Such see-through display apparatuses can be provided even in the automobile windshield without hindering the view. In the case where a driving transistor or the like is provided, a transistor having a light-transmitting property, such as an organic transistor including an organic semiconductor material or a transistor including an oxide semiconductor, is preferably used.

The display region 5202 is a display apparatus which is provided in a pillar portion and includes the light-emitting device described in Embodiment 1 and Embodiment 2. The display region 5202 can compensate for the view hindered by the pillar by displaying a video taken by an imaging unit provided in the car body. Similarly, the display region 5203 provided in the dashboard portion can compensate for the view hindered by the car body by displaying a video taken by an imaging unit provided on the outside of the automobile; thus, blind areas can be eliminated to enhance the safety. Videos that compensate for the areas which a driver cannot see enable the driver to ensure safety easily and comfortably.

The display region 5203 can provide a variety of kinds of information such as navigation data, the speed, the number of rotations, and air-condition setting. The content or layout of the display can be changed as appropriate according to the user's preference. Note that such information can also be displayed on the display region 5200 to the display region 5202. The display region 5200 to the display region 5203 can also be used as lighting devices.

FIG. 16A and FIG. 16B illustrate a foldable portable information terminal 5150. The foldable portable information terminal 5150 includes a housing 5151, a display region 5152, and a bend portion 5153. FIG. 16A illustrates the portable information terminal 5150 that is opened. FIG. 16B illustrates the portable information terminal that is folded. Despite its large display region 5152, the portable information terminal 5150 is compact in size and has excellent portability when folded.

The display region 5152 can be folded in half with the bend portion 5153. The bend portion 5153 includes a flexible member and a plurality of supporting members. When the display region is folded, the flexible member expands. The bend portion 5153 has a radius of curvature greater than or equal to 2 mm, preferably greater than or equal to 3 mm.

Note that the display region 5152 may be a touch panel (an input/output device) including a touch sensor (an input device). The light-emitting apparatus of one embodiment of the present invention can be used for the display region 5152.

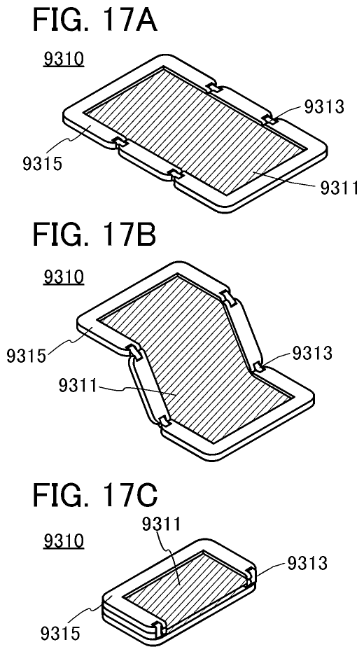

FIG. 17A to FIG. 17C illustrate a foldable portable information terminal 9310. FIG. 17A illustrates the portable information terminal 9310 that is opened. FIG. 17B illustrates the portable information terminal 9310 on the way from either the opened state or the folded state to the other state. FIG. 17C illustrates the portable information terminal 9310 that is folded. The portable information terminal 9310 is highly portable when folded, and is highly browsable when opened because of a seamless large display region.

A display panel 9311 is supported by three housings 9315 joined together by hinges 9313. Note that the display panel 9311 may be a touch panel (an input/output device) including a touch sensor (an input device). By folding the display panel 9311 at the hinges 9313 between two housings 9315, the portable information terminal 9310 can be reversibly changed in shape from the opened state to the folded state. The light-emitting apparatus of one embodiment of the present invention can be used for the display panel 9311.

At least part of any of the structure examples, the drawings corresponding thereto, and the like described in this embodiment can be combined with any of the other structure examples, the other drawings, and the like as appropriate.

At least part of this embodiment can be implemented in combination with the other embodiments described in this specification as appropriate.

### Example 1

In this example, a light-emitting device 1 and a light-emitting device 2 of one embodiment of the present invention and a comparative light-emitting device 1 will be described. Structural formulae of organic compounds used in this example are shown below.

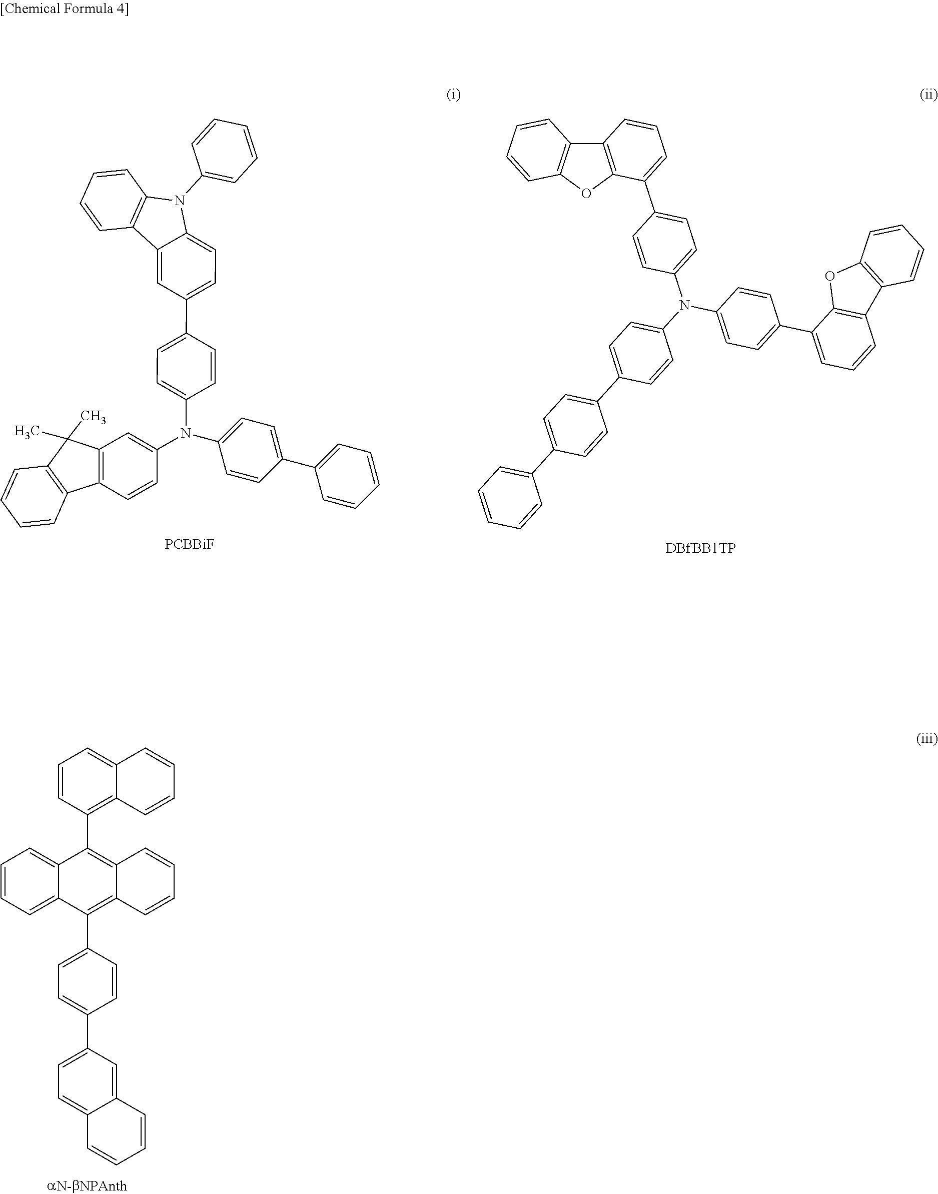

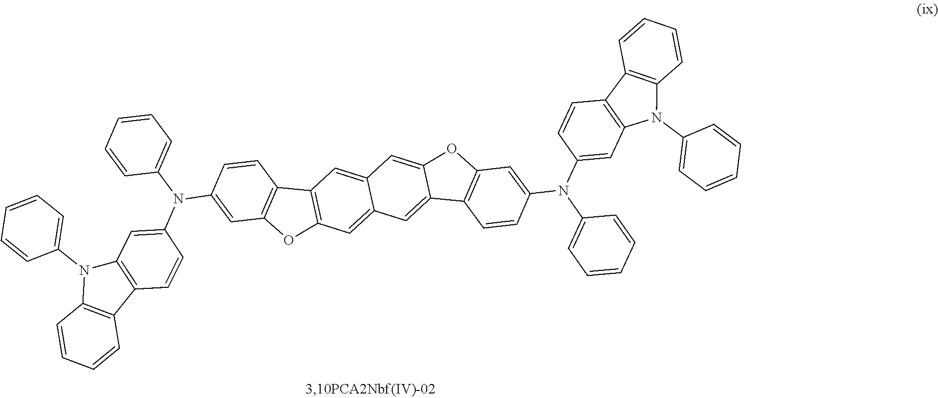 [SMILES: c1ccc(N(c2ccc3c(c2)oc2cc4cc5c(cc4cc23)oc2cc(N(c3ccccc3)c3ccc4c6ccccc6n(-c6ccccc6)c4c3)ccc25)c2ccc3c4ccccc4n(-c4ccccc4)c3c2)cc1]

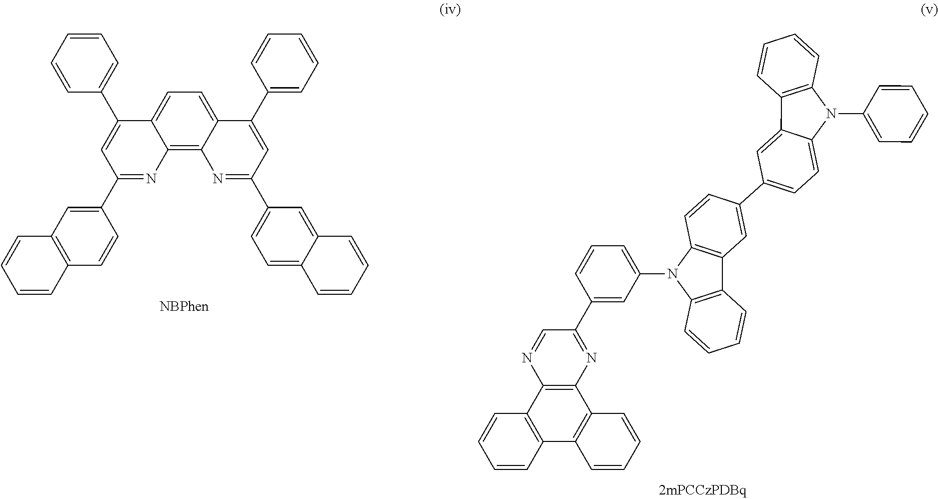 [SMILES: c1ccc(-c2cc(-c3ccc4ccccc4c3)nc3c2ccc2c(-c4ccccc4)cc(-c4ccc5ccccc5c4)nc23)cc1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1]

### (Method for Fabricating Light-Emitting Device 1)

First, 400-nm-thick silicon oxide was deposited as an insulating film over a silicon substrate by a CVD method, and then heating was performed at 350° C. in a nitrogen atmosphere for 1 hour. After that, 50-nm-thick titanium, 70-nm-thick aluminum, and 6-nm-thick titanium were deposited by a sputtering method, and heating was performed at 300° C. for 1 hour to form a reflective electrode. Then, as a transparent electrode, 10-nm-thick indium tin oxide containing silicon oxide (ITSO) was deposited by a sputtering method. Subsequently, a photomask was formed by a photolithography method, and then the ITSO and the stacked layers of titanium, aluminum, and titanium were respectively patterned by wet etching and dry etching, whereby the pixel electrode 101 having a width of 3 μm was formed. Note that the transparent electrode functions as the anode, and the transparent electrode and the reflective electrode can be collectively regarded as the pixel electrode (anode) 101.

Next, O₂ ashing treatment (the substrate temperature was 40° C., the pressure was 0.67 Pa, the O₂ flow rate was 200 sccm, the ICP power was 2000 W, the substrate bias was 50 W, and the treatment time was 30 seconds) was performed, and then the photomask was removed.

After that, the substrate was transferred into a vacuum evaporation apparatus in which the pressure was reduced to approximately 1×10⁻⁴ Pa, vacuum baking was performed at 170° C. for 60 minutes in a heating chamber of the vacuum evaporation apparatus, and then the substrate was cooled down for approximately 30 minutes.

Next, the substrate over which the pixel electrode 101 was formed was fixed to a substrate holder provided in the vacuum evaporation apparatus such that the surface over which the pixel electrode 101 was formed faced downward. Over the pixel electrode 101, N-(1,1′-biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (i) above and a fluorine-containing electron-acceptor material with a molecular weight of 672 (OCHD-003) were deposited by co-evaporation using resistance heating to a thickness of 10 nm such that the weight ratio was 1:0.03 (=PCBBiF: OCHD-003), whereby the hole-injection layer 111 was formed.

Next, over the hole-injection layer 111, PCBBiF was deposited by evaporation to a thickness of 96 nm to form the hole-transport layer 112.

Subsequently, N,N-bis[4-(dibenzofuran-4-yl)phenyl]-4-amino-p-terphenyl (abbreviation: DBfBB1TP) represented by Structural Formula (ii) above was deposited by evaporation to a thickness of 10 nm to form an electron-blocking layer.

Then, 9-(1-naphthyl)-10-[4-(2-naphthyl)phenyl]anthracene (abbreviation: (N-βNPAnth) represented by Structural Formula (iii) above and 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02) represented by Structural Formula (ix) above were deposited by co-evaporation to a thickness of 25 nm such that the weight ratio was 1:0.015 (=αN-βNPAnth: 3,10PCA2Nbf(IV)-02), whereby the light-emitting layer 113 was formed.

After that, over the light-emitting layer 113, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (v) above was deposited by evaporation to a thickness of 20 nm to form a hole-blocking layer, and then, 2,9-di(2-naphthyl)-4,7-diphenyl-1,10-phenanthroline (abbreviation: NBPhen) represented by Structural Formula (vi) above was deposited by evaporation to a thickness of 15 nm to form the electron-transport layer 114.

Then, in the light-emitting device 1 where the components up to the electron-transport layer 114 were formed, a 30-nm-thick aluminum oxide film was formed by an ALD (Atomic Layer Deposition) method at 80° C. using trimethylaluminum (abbreviation: TMA) as a precursor and water vapor as an oxidizer. Next, 50-nm-thick tungsten (W) was deposited by a sputtering method under an argon stream at a pressure of 2.1 Pa at a substrate temperature of 50° C.

After that, a 700-nm-thick positive photoresist was applied and then subjected to light exposure and development, whereby a photomask larger than the pixel electrode 101 was formed.

Next, the tungsten film was removed by a dry etching method using the formed photomask as a mask and SF₆ as an etching gas. Then, the photomask was removed by O₂ ashing (the substrate temperature was 10° C., the pressure was 5.00 Pa, the O₂ flow rate was 80 sccm, the ICP power was 800 W, the substrate bias was 10 W, and the treatment time was 15 seconds). After that, the aluminum oxide film was removed by dry etching using the tungsten film as a mask, and the layers from the hole-injection layer 111 to the electron-transport layer 114 (the first EL layer) were patterned by dry etching using the tungsten film and the aluminum oxide film as a mask.

Then, the tungsten film was removed by dry etching using SF₆, and a 10-nm-thick aluminum oxide film was deposited by an ALD method at 80° C. using trimethylaluminum (abbreviation: TMA) as a precursor and water vapor as an oxidizer to cover the top and side surfaces of the exposed aluminum oxide and the side surface of the first EL layer.

Next, a 400-nm-thick photosensitive organic resin was applied and then subjected to light exposure and development, whereby an insulating layer with an opening portion overlapping with the pixel electrode 101 and having an opening area of 7.32 μm² was formed. After O₂ ashing followed by baking at 100° C. under reduced pressure for 1 hour, the aluminum oxide film exposed in the opening portion was subjected to wet etching using a developing solution for 253 seconds to be removed.

After that, the substrate was transferred into a vacuum evaporation apparatus in which the pressure was reduced to approximately 1×10⁻⁴ Pa, vacuum baking was performed at 70° C. for 90 minutes in a heating chamber of the vacuum evaporation apparatus, lithium fluoride (LiF) and ytterbium (Yb) were deposited by co-evaporation to a thickness of 2 nm at a volume ratio of 1:1 to form the electron-injection layer 115, and lastly silver (Ag) and magnesium (Mg) were deposited by co-evaporation to a thickness of 25 nm at a volume ratio of 1:0.1 and a 70-nm-thick indium oxide-tin oxide (ITO) was deposited to form the cathode (common electrode) 102, whereby the light-emitting device 1 was fabricated. Note that the common electrode 102 is a transflective electrode having a function of reflecting light and a function of transmitting light; thus, the light-emitting device 1 is a top-emission element in which light is extracted through the common electrode 102.

### (Method for Fabricating Light-Emitting Device 2)

The light-emitting device 2 was fabricated through substantially the same process and in substantially the same layout as the light-emitting device 1 except that a different photosensitive organic resin was used, baking was performed at 90° C. for 90 seconds after application, and then light exposure and development were performed to form an insulating layer having an opening portion overlapping with the pixel electrode 101. After that, light irradiation was performed for 86 seconds using an ultra-high-pressure mercury lamp and baking was performed at 100° C. for 600 seconds; these are also differences from the light-emitting device 1. Accordingly, the inner side surface of the opening portion of the insulating layer was tapered, leading to good coverage with films to be formed later.

### (Method for Fabricating Comparative Light-Emitting Device 1)

The components of the comparative light-emitting device 1 up to the pixel electrode 101 were formed in the same manner as those of the light-emitting device 1; after that, heating was performed under a reduced pressure of approximately 1×10⁻⁴ Pa at a substrate temperature of 250° C. for 5 minutes and 150-nm-thick silicon oxide was deposited by a sputtering method to form an inorganic insulating layer.

Then, the inorganic insulating layer was subjected to dry etching by a photolithography method, so that an opening portion overlapping with the pixel electrode and having an opening area of 7.32 μm² was formed. After O₂ ashing, the resist was removed.

After that, the substrate was transferred into a vacuum evaporation apparatus in which the pressure was reduced to approximately 1×10⁻⁴ Pa, vacuum baking was performed at 170° C. for 60 minutes in a heating chamber of the vacuum evaporation apparatus, and then the substrate was cooled down for approximately 30 minutes.

Next, the layers from the hole-injection layer 111 to the electron-transport layer 114 were formed in the same manner as those of the light-emitting device 1, and successively after the formation of the electron-transport layer, lithium fluoride (LiF) and ytterbium (Yb) were deposited by co-evaporation to a thickness of 2 nm at a volume ratio of 1:1 to form the electron-injection layer 115. Lastly, silver (Ag) and magnesium (Mg) were deposited by co-evaporation to a thickness of 25 nm at a volume ratio of 1:0.1 and a 70-nm-thick indium oxide-tin oxide (ITO) was deposited to form the cathode (common electrode) 102, whereby the comparative light-emitting device 1 was fabricated. Note that the common electrode 102 is a transflective electrode having a function of reflecting light and a function of transmitting light; thus, the comparative light-emitting device 1 is a top-emission element in which light is extracted through the common electrode 102.

The stacked-layer structures of the light-emitting device 1, the light-emitting device 2, and the comparative light-emitting device 1 are listed in the following table.

TABLE 1

| | Thick- | |
|---|---|---|
| | ness | |
| Functional layer | (nm) | Structure |
| Electron-injection layer | 2 | LiF:Yb (1:1) |
| Electron-transport layer | 15 | NBPhen |
| Hole-blocking layer | 20 | 2mPCCzPDBq |
| Light-emitting layer | 25 | αN-βNPAnth:3,10PCA2Nbf(IV)-02 |
| | | (1:0.015) |
| Electron-blocking layer | 10 | DBfBB1TP |
| Hole-transport layer | 96 | PCBBiF |
| Hole-injection layer | 10 | PCBBiF:OCHD-003 (1:0.03) |

The light-emitting device 1, the light-emitting device 2, and the comparative light-emitting device 1 were subjected to sealing with a glass substrate (a sealing material was applied to surround the elements, and UV treatment and heat treatment at 80° C. for one hour were performed at the time of sealing) in a glove box containing a nitrogen atmosphere so that the light-emitting devices were not exposed to the air. After that, the initial characteristics of the light-emitting device 1, the light-emitting device 2, and the comparative light-emitting device 1 were measured.

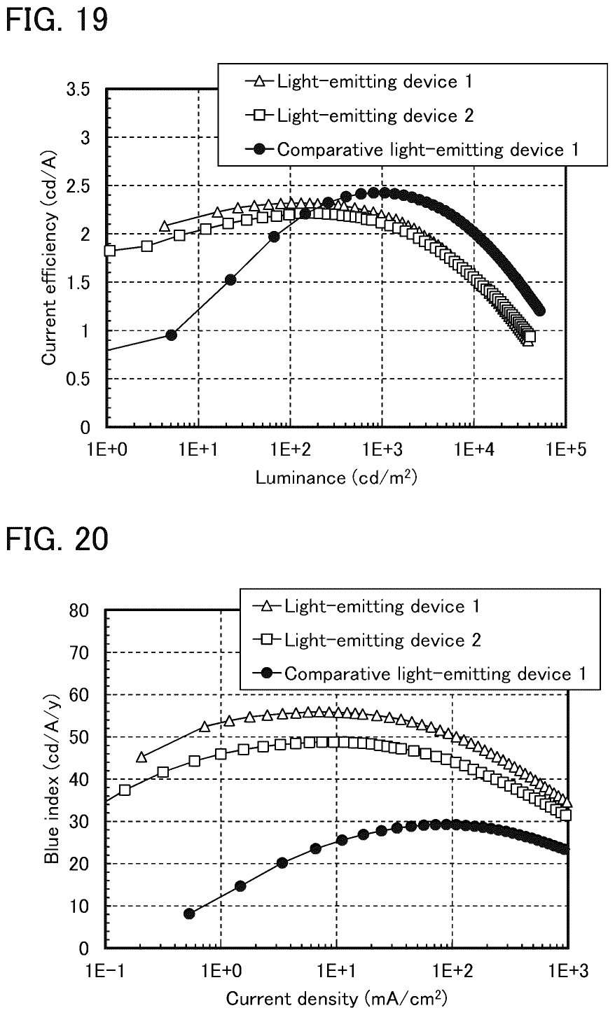

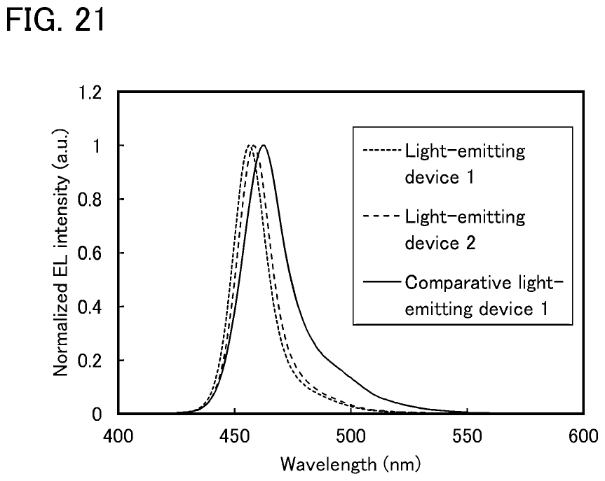

FIG. 19 shows the current efficiency-luminance characteristics of the light-emitting device 1, the light-emitting device 2, and the comparative light-emitting device 1, FIG. 20 shows the blue index-current density characteristics thereof, and FIG. 21 shows the emission spectra thereof.

In addition, the main characteristics at around 1000 cd/m² are listed in the following table. The luminance, CIE chromaticity, and emission spectra were measured using a spectroradiometer (SR-UL1R, produced by TOPCON TECHNOHOUSE CORPORATION). Note that the measurements of the light-emitting devices were performed at room temperature (in an atmosphere maintained at 23° C.).

TABLE 2

| | | Current | | | Current | |
|---|---|---|---|---|---|---|
| | Voltage | density | Chromaticity | Chromaticity | efficiency | BI |
| | (V) | (mA/cm²) | x | y | (cd/A) | (cd/A/y) |
| Light-emitting | 5.4 | 45.6 | 0.14 | 0.04 | 2.2 | 54 |
| device 1 | | | | | | |
| Light-emitting | 5.2 | 47.4 | 0.14 | 0.05 | 2.1 | 47 |
| device 2 | | | | | | |
| Comparative | 4.5 | 41.3 | 0.13 | 0.08 | 2.4 | 29 |
| light-emitting | | | | | | |
| device 1 | | | | | | |

FIG. 19 reveals that the current efficiency of the light-emitting device 1 and the light-emitting device 2 is lower than that of the comparative light-emitting device. However, the light-emitting device 1 and the light-emitting device 2 have smaller chromaticity y than the comparative light-emitting device 1 and thus emit deep-blue light. Accordingly, the light-emitting device 1 and the light-emitting device 2 each have a higher blue index than the comparative light-emitting device 1 as shown in FIG. 20.

Note that the blue index (BI) is a value obtained by dividing current efficiency (cd/A) by chromaticity y, and is one of the indicators of characteristics of blue light emission. As the chromaticity y is smaller, the color purity of blue light emission tends to be higher. With high color purity for blue light emission, a wide range of blue can be expressed even with a small number of luminance components; thus, using blue light emission with high color purity reduces the luminance needed for expressing blue, leading to lower power consumption. Thus, BI that is based on chromaticity y, which is one of the indicators of color purity of blue, is suitably used as a means for showing efficiency of blue light emission. The light-emitting device with higher BI can be regarded as a blue-light-emitting device having higher efficiency for a display.

That is, it is found that the light-emitting device 1 and the light-emitting device 2 have lower current efficiency than the comparative light-emitting device 1 but emit deep-blue light and thus have excellent characteristics of blue-light-emitting devices.

Note that according to the emission spectra in FIG. 21, the peak wavelength of the emission spectrum of the comparative light-emitting device 1 is shifted to the longer wavelength side and the half width of the peak of the spectrum is large. It is also found from the above table that the chromaticity y of the comparative light-emitting device 1 is twice or approximately twice those of the light-emitting device 1 and the light-emitting device 2.

The above results demonstrate that the light-emitting device 1 and the light-emitting device 2 have better characteristics as blue-light-emitting devices than the comparative light-emitting device 1.

Note that the above results are attributed to an emission wavelength change due to leakage current in the comparative light-emitting device 1. As illustrated in FIG. 2A, in the comparative light-emitting device 1, the common electrode (cathode) 102 is in contact with the EL layer in a larger area than the pixel electrode 101. Hence, current flows not only to the common electrode that is in a position overlapping with the opening portion of the inorganic insulating film but also to the common electrode that is positioned in its peripheral portion. The emission position of light excited by such leakage current is different from the assumed position; thus, the optical path length of part of light from the inside of the light-emitting device to the outside of the device may shift from the assumed wavelength range. Light emitted in a region without the pixel electrode 101 is not resonated between the pixel electrode 101 and the common electrode (cathode) 102; hence, the light with a broad spectrum shape is emitted to the outside. The angle of the common electrode varies depending on the position because of the unevenness of the inorganic insulating film; thus, such light is easily emitted to the outside of the light-emitting device. For these reasons, light with a longer wavelength than the assumed wavelength and light whose spectrum has a large half width (is broad) are mixed in light emitted from the comparative light-emitting device 1, so that the emission spectrum changes.

By contrast, in each of the light-emitting device 1 and the light-emitting device 2, the common electrode 102 overlaps with the EL layer in the opening portion of the insulating layer. Since leakage current hardly flows to the peripheral portion of the common electrode 102 and light with a different wavelength is unlikely to be mixed, light emission with high color purity can be obtained and the light-emitting devices can each have a high blue index. Furthermore, in each of the light-emitting device 1 and the light-emitting device 2, the layers from the hole-injection layer 111 to the electron-transport layer 114 were etched, 40-nm-thick aluminum oxide was formed on the upper portion of the EL layer that was not covered with the common electrode (the electron-injection layer), and 10-nm-thick aluminum oxide was formed on the side surface of the EL layer. This also inhibits leakage current from flowing through the EL layer. The emission of light with a different optical path length to the outside can be inhibited, so that the light-emitting devices can have better characteristics.

Described next are examination results of the relationships of the measurement positions with the emission intensities and the spectrum shapes of the light-emitting device 2 and the comparative light-emitting device 1 obtained with a 2D spectroradiometer (SR-5100HM produced by TOPCON TECHNOHOUSE CORPORATION).

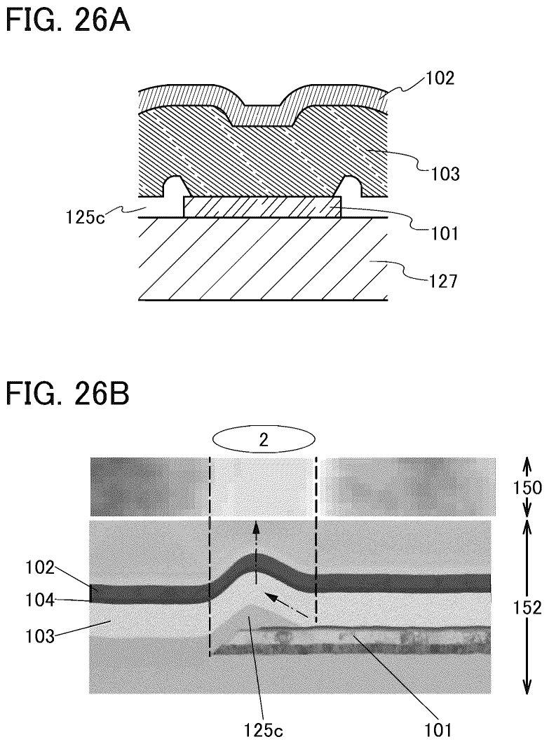

Note that the structure of the light-emitting device 2 corresponds to the structure illustrated in FIG. 1A in Embodiment 1, and the structure of the comparative light-emitting device 1 corresponds to a structure illustrated in FIG. 26A. The structure illustrated in FIG. 26A includes an insulating layer 127, the pixel electrode (anode) 101 over the insulating layer 127, an insulating layer 125c covering the side surface and part of the top surface of the pixel electrode (anode) 101, the EL layer 103 provided to cover the pixel electrode (anode) 101 and the insulating layer 125c, an electron-injection layer 104 over the EL layer 103, and the common electrode (cathode) 102 provided over the electron-injection layer 104.

The light-emitting device 2 having the structure corresponding to that illustrated in FIG. 1A greatly differs from the comparative light-emitting device 1 illustrated in FIG. 26A in that the insulating layer 125c covering the side surface and part of the top surface of the pixel electrode (anode) 101 is not provided and the EL layer 103 is divided.

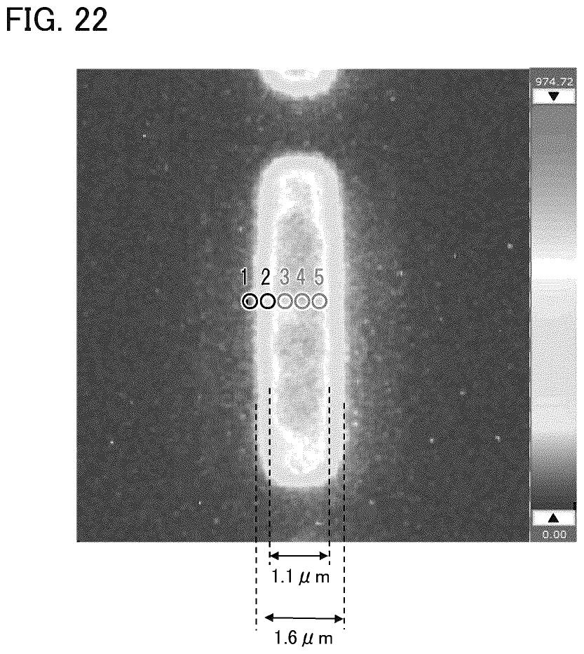

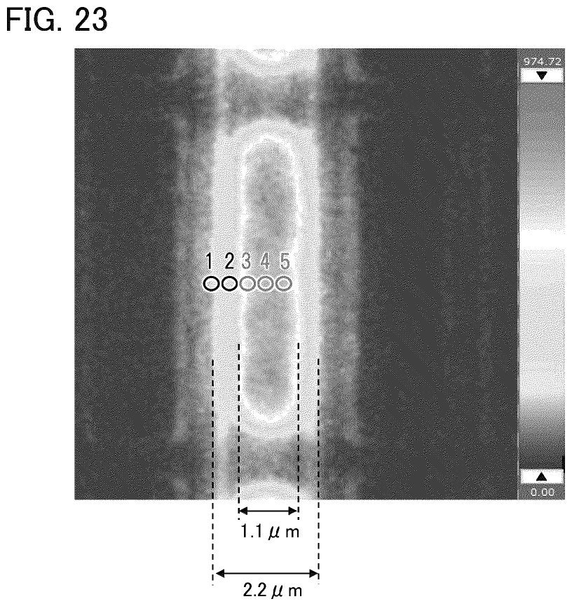

FIG. 22 and FIG. 23 show 2D spectroradiometer measurement results of the light-emitting device 2 and the comparative light-emitting device 1 that emit light at a current density of 10 mA/cm². Colors of images in FIG. 22 and FIG. 23 are associated with emission intensities.

In FIG. 22 (the light-emitting device 2), the center portion of the image is a bright region having a width of 1.1 μm, its periphery up to a width of 1.6 μm is a region with a slightly low luminance, and a region outside these regions emits almost no light. Since the width of the opening portion provided in the photosensitive organic resin of the light-emitting device 2 is 1.14 μm, the region having a width of 1.1 μm in the center portion of the image is found to be a region where the pixel electrode and the EL layer are in contact with each other.

Meanwhile, in FIG. 23 (the comparative light-emitting device 1), the center portion of the image is a bright region having a width of 1.1 μm, its periphery up to a width of 2.2 μm is a region with a slightly low luminance, and light is spread out in a region outside these regions. Since the design value of the width of the opening portion in the inorganic insulating film of the comparative light-emitting device 1 is 1.14 μm, the region having a width of 1.1 μm in the center portion of the image is found to be a region where the pixel electrode and the EL layer are in contact with each other. A wider range of light emission is observed in the comparative light-emitting device 1 than in the light-emitting device 2.

In order to examine the factor of this light emission spread, light-emitting devices including hole-injection layers with different acceptor substance concentrations were fabricated on the basis of the structure of the comparative light-emitting device 1, and the measurement was performed in the same manner; as a result, it is found that the light-emitting device in which the amount of acceptor substance is larger and the resistance of the hole-injection layer is lower has a larger width of a light-emitting portion spreading outside the opening portion and thus has higher luminance. That is, it is suggested that the light emission spreading outside the opening portion of the comparative light-emitting device 1 is light emission in the periphery of the opening portion caused by leakage current through the hole-injection layer.

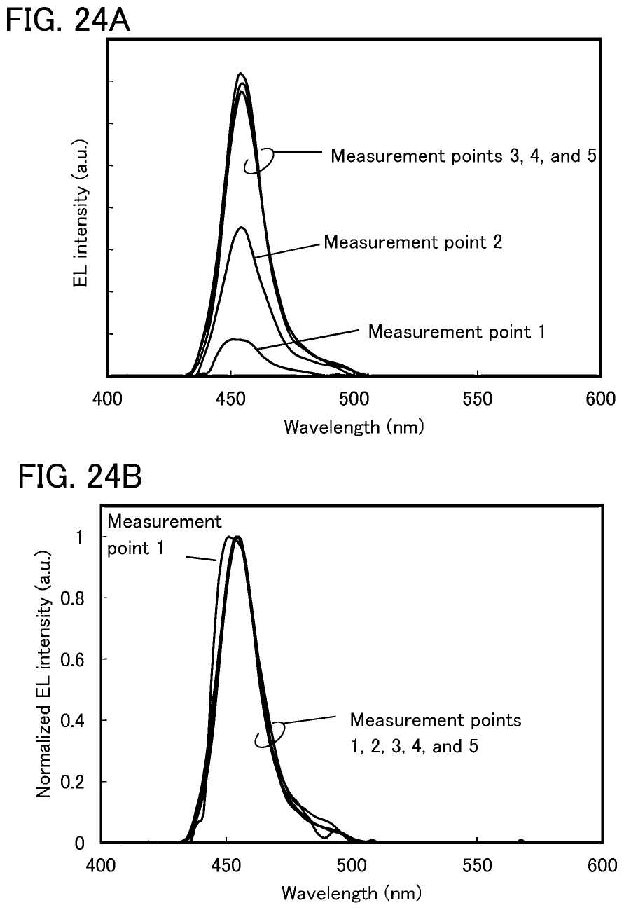

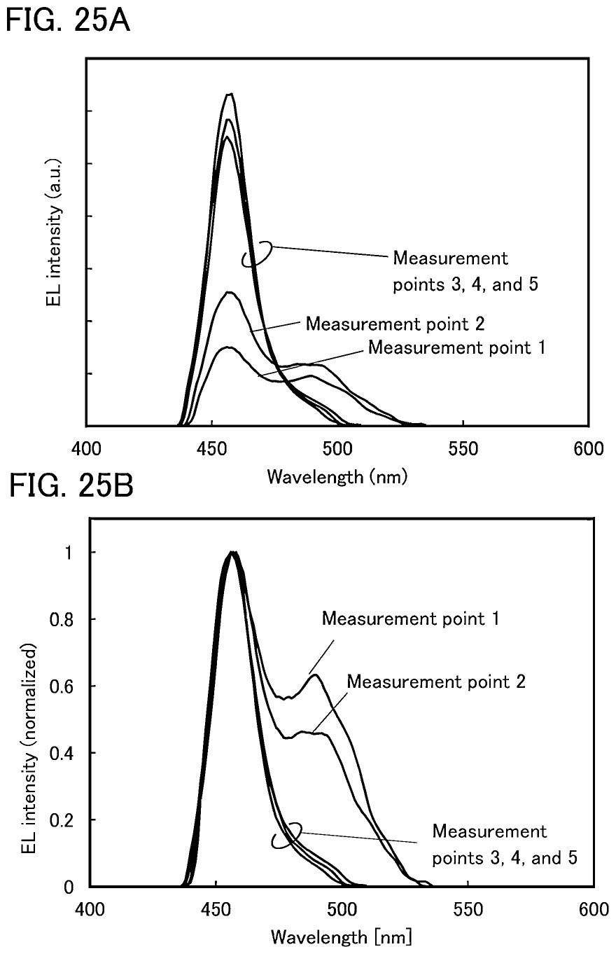

Next, FIG. 24A, FIG. 24B, FIG. 25A, and FIG. 25B show measurement results of the emission spectra of the light-emitting devices at different measurement points. FIG. 24 shows the emission spectra of the light-emitting device 2 at different measurement points, and FIG. 25 shows the emission spectra of the comparative light-emitting device 1 at different measurement points. The measurement points correspond to the positions indicated by circles with 1 to 5 in FIG. 22 and FIG. 23.

It is found from FIG. 24A and FIG. 25A that there are almost no differences in the spectrum intensity and the spectrum shape between the measurement points 3, 4, and 5 corresponding to the opening portion, and as for the measurement point 2 and the measurement point 1, the maximum emission intensity becomes lower as the distance from the opening portion becomes longer.

FIG. 24B and FIG. 25B are diagrams showing the spectra in FIG. 24A and FIG. 25A that are normalized by the maximum emission intensity. FIG. 24B reveals that there is almost no difference in the emission spectrum of the light-emitting device 2 between the measurement positions. Meanwhile, FIG. 25B reveals that there is no large difference in the emission spectrum shape of the comparative light-emitting device 1 between the measurement points 3, 4, and 5 corresponding to the opening portion but peaks at around 500 nm are observed and the spectrum shapes are significantly changed at the measurement point 2 and the measurement point 1 away from the opening portion. This is because light emission is caused in a position different from the assumed position owing to leakage current through the hole-injection layer and thus light is emitted through a cavity with a different optical path length or not through a cavity.

Since light emission with a different spectrum shape is mixed in the periphery of the opening portion in the comparative light-emitting device 1, it is found that the emission spectrum shape of the entire light-emitting device changes and the chromaticity is deviated. The luminance needed for a blue-light-emitting device used in a display is closely related to the chromaticity. Therefore, an increase in chromaticity y due to mixing of light emission in a long wavelength range with light emission in the peripheral region of the comparative light-emitting device 1 significantly degrades the BI.

Here, in order to examine the mechanism of decreasing the chromaticity of the comparative light-emitting device 1 and significantly degrading the BI thereof, cross-sectional STEM (Scanning Transmission Electron Microscope) observation of the comparative light-emitting device 1 was performed. FIG. 26B shows the result of a cross-sectional STEM image of the comparative light-emitting device 1 and the result of a 2D spectroradiometer measurement image.

In FIG. 26B, a region 150 shows part of the 2D spectroradiometer measurement image, and a region 152 shows the result of the cross-sectional STEM image. That is, FIG. 26B is a diagram obtained by combining part of the 2D spectroradiometer measurement image and the cross-sectional STEM image. Note that the region 150 is an extracted part of the 2D spectroradiometer measurement image shown in FIG. 23 that is enlarged to match the cross-sectional STEM image. A region of the measurement point 2 that is enclosed in a circle above the region 150 corresponds to the measurement point 2 shown in FIG. 23.

As shown in FIG. 26B, in the comparative light-emitting device 1, current flowing through the EL layer 103 has an influence on the top surface of the insulating layer 125c in the periphery of the opening portion as indicated by dashed arrows; thus, leakage current might be generated in the horizontal direction through the EL layer 103, specifically the hole-injection layer formed in the lower portion of the EL layer 103. As a result, light emission from the EL layer 103 is observed also in the upper portion of the insulating layer 125c, so that the optical path length is changed and the resonance wavelength is changed. It is thus suggested that light emission from the EL layer 103 in a region overlapping with the insulating layer 125c becomes broad and the spectrum shape is changed as shown in FIG. 25A and FIG. 25B.

Meanwhile, such a spectrum change does not occur in the light-emitting device of one embodiment of the present invention, and the light-emitting device can have a high BI. Note that the light-emitting device of one embodiment of the present invention has the structure illustrated in FIG. 1A in which an insulating layer (also referred to as a structure body or a bank) covering the side surface and part of the top surface of the pixel electrode (anode) is not provided. Thus, the light-emitting device of one embodiment of the present invention can have a sharper emission spectrum and higher BI than the light-emitting device having the structure in which the insulating layer covering the side surface and part of the top surface of the pixel electrode (anode) is provided.

Note that these phenomena occur in the peripheral portion (the periphery of the portion where the pixel electrode, the EL layer, and the common electrode overlap with one another) in the light-emitting device and thus are more noticeable in a higher-resolution light-emitting apparatus. Therefore, the structure of one embodiment of the present invention is extremely suitable for a high-resolution light-emitting apparatus.

### REFERENCE NUMERALS

100: substrate, 101B: pixel electrode, 101C: connection electrode, 101G: pixel electrode, 101R: pixel electrode, 101: pixel electrode, 102: common electrode, 103: EL layer, 103(1): first EL layer, 103(2): second EL layer, 104: electron-injection layer, 107: mask layer, 108: insulating layer, 110B: light-emitting device, 110G: light-emitting device, 110R: light-emitting device, 111: hole-injection layer, 112: hole-transport layer, 113: light-emitting layer, 114: electron-transport layer, 115: electron-injection layer, 121: second EL layer, 120B: EL layer, 120Bb: EL film, 120G: EL layer, 120Gb: EL film, 120R: EL layer, 120Rb: EL film, 120: first EL layer, 121: EL layer, 124: insulating layer, 125: insulating layer, 125b: insulating layer, 125c: insulating layer, 126: insulating layer, 126b: insulating layer, 127: insulating layer, 127a: insulating layer, 128: opening portion, 129: insulating layer, 130: connection portion, 131: protective layer, 143a: resist mask, 144a: mask film, 145a: mask layer, 145b: mask layer, 145c: mask layer, 146a: protective film, 146b: protective film, 146c: protective film, 147a: protective layer, 150: region, 152: region, 400: substrate, 401: anode, 403: EL layer, 404: cathode, 405: sealing material, 406: sealing material, 407: sealing substrate, 412: pad, 420: IC chip, 450: light-emitting apparatus, 601: source line driver circuit, 602: pixel portion, 603: gate line driver circuit, 604: sealing substrate, 605: sealing material, 607: space, 608: lead wiring, 610: element substrate, 611: switching FET, 612: current controlling FET, 613: first electrode, 614: insulator, 616: EL layer, 617: second electrode, 618: light-emitting device, 623: FET, 951: substrate, 952: electrode, 953: insulating layer, 954: partition layer, 955: EL layer, 956: electrode, 1001: substrate, 1002: base insulating film, 1003: gate insulating film, 1006: gate electrode, 1007: gate electrode, 1008: gate electrode, 1020: first interlayer insulating film, 1021: second interlayer insulating film, 1022: electrode, 1024B: anode, 1024G: anode, 1024R: anode, 1025: partition, 1028: EL layer, 1029: cathode, 1031: sealing substrate, 1032: sealing material, 1033: base material, 1034B: coloring layer, 1034G: coloring layer, 1034R: coloring layer, 1035: black matrix, 1036: overcoat layer, 1037: third interlayer insulating film, 1040: pixel portion, 1041: driver circuit portion, 1042: peripheral portion, 2001: housing, 2002: light source, 2100: robot, 2101: illuminance sensor, 2102: microphone, 2103: upper camera, 2104: speaker, 2105: display, 2106: lower camera, 2107: obstacle sensor, 2108: moving mechanism, 2110: arithmetic device, 3001: lighting device, 5000: housing, 5001: display portion, 5002: second display portion, 5003: speaker, 5004: LED lamp, 5006: connection terminal, 5007: sensor, 5008: microphone, 5012: support portion, 5013: earphone, 5100: cleaning robot, 5101: display, 5102: camera, 5103: brush, 5104: operation button, 5120: dust, 5140: portable electronic appliance, 5150: portable information terminal, 5151: housing, 5152: display region, 5153: bend portion, 5200: display region, 5201: display region, 5202: display region, 5203: display region, 7101: housing, 7103: display portion, 7105: stand, 7107: display portion, 7109: operation key, 7110: remote controller, 7201: main body, 7202: housing, 7203: display portion, 7204: keyboard, 7205: external connection port, 7206: pointing device, 7210: display portion, 7401: housing, 7402: display portion, 7403: operation button, 7404: external connection port, 7405: speaker, 7406: microphone, 9310: portable information terminal, 9311: display panel, 9313: hinge, 9315: housing

1.-3. (canceled)

4. A light-emitting apparatus comprising:
a first pixel electrode;
a second pixel electrode adjacent to the first pixel electrode;
a common electrode;
a first EL layer between the first pixel electrode and the common electrode;
a second EL layer between the second pixel electrode and the common electrode; and
an insulating layer between the common electrode and each of the first EL layer and the second EL layer,
wherein the insulating layer comprises a first opening portion overlapping with the first pixel electrode and a second opening portion overlapping with the second pixel electrode,
wherein the first EL layer comprises a third EL layer comprising a first light-emitting layer and a fourth EL layer positioned between the third EL layer and the common electrode,
wherein the second EL layer comprises a fifth EL layer comprising a second light-emitting layer and the fourth EL layer positioned between the fifth EL layer and the common electrode,
wherein the first light-emitting layer comprises a first light-emitting substance,
wherein the first light-emitting substance is configured to emit blue light,
wherein the third EL layer is in contact with the first pixel electrode,
wherein the fifth EL layer is in contact with the second pixel electrode,
wherein the fourth EL layer is in contact with the third EL layer in the first opening portion, and
wherein the fourth EL layer is in contact with the fifth EL layer in the second opening portion.

5. The light-emitting apparatus according to claim 4, wherein the fourth EL layer is positioned between and in contact with the insulating layer and the common electrode in a region overlapping with neither the first pixel electrode nor the second pixel electrode.

6. The light-emitting apparatus according to claim 4,
wherein an end portion of the first pixel electrode is covered with the third EL layer, and
wherein an end portion of the second pixel electrode is covered with the fifth EL layer.

7. The light-emitting apparatus according to claim 4,
wherein an end portion of the third EL layer is covered with the insulating layer, and
wherein an end portion of the fifth EL layer is covered with the insulating layer.

8. The light-emitting apparatus according to claim 4, wherein the insulating layer comprises an organic compound.

9. The light-emitting apparatus according to claim 4,
wherein side surfaces of the first opening portion and the second opening portion have tapered shapes, and
wherein an angle of each of the tapered shapes is less than 90°.

10. The light-emitting apparatus according to claim 4, wherein a distance between end portions of the first pixel electrode and the second pixel electrode is longer than or equal to 0.5 μm and shorter than or equal to 5 μm.

11. The light-emitting apparatus according to claim 4, wherein an area of a portion where the first EL layer is in contact with the first pixel electrode and the common electrode, and the first pixel electrode, the first EL layer, and the common electrode overlap with one another is greater than or equal to 5 μm² and less than or equal to 15 μm².

12. The light-emitting apparatus according to claim 4, wherein a half width of an emission spectrum of the first EL layer in the first opening portion is less than or equal to 20 nm.
